(19) United States
(12) Patent Application Publication
(10) Pub. No.: US 2026/0090008 A1
(43) Pub. Date: Mar. 26, 2026

(54) SEMICONDUCTOR DEVICE AND METHOD OF MANUFACTURING THE SAME

(71) Applicant: Renesas Electronics Corporation, Tokyo (JP)

(72) Inventor: Keiichi FURUYA, Tokyo (JP)

(21) Appl. No.: 19/230,296

(22) Filed: Jun. 6, 2025

(30) Foreign Application Priority Data
Sep. 20, 2024 (JP) 2024-163928

(51) Int. Cl. H10D 30/65; H01L 21/762; H10D 8/01; H10D 8/25; H10D 30/01; H10D 62/10; H10D 62/60

(52) U.S. Cl. CPC H10D 30/655; H10D 8/022; H10D 8/25; H10D 30/0281; H10D 62/106; H10D 62/124; H10D 62/60; H10W 10/0145; H10W 10/17

(57) ABSTRACT

A semiconductor substrate includes a p-type substrate region, an n-type buried layer on the p-type substrate region, and a p-type semiconductor layer on the n-type buried layer. A DTI region is formed in a trench that penetrates through the p-type semiconductor layer and the n-type buried layer, reaching the p-type substrate region. A plurality of scallops are formed at a side surface of the trench. A size of each of a plurality of first scallops formed at the side surface of the trench in the p-type semiconductor layer is larger than a size of each of a plurality of second scallops formed at the side surface of the trench in the n-type buried layer.

### CROSS-REFERENCE TO RELATED APPLICATIONS

The disclosure of Japanese Patent Application No. 2024-163928 filed on Sep. 20, 2024, including the specification, drawings and abstract is incorporated herein by reference in its entirety.

### BACKGROUND

The present invention relates to a semiconductor device and a method of manufacturing the same and can be suitably used for a semiconductor device including a DTI region and a method of manufacturing the same.

There are disclosed techniques listed below.

### [Patent Document 1] Japanese Unexamined Patent Application Publication No. 2011-66067

Patent Document 1 discloses a semiconductor device having a DTI structure.

### SUMMARY

It is also desired to improve the performance of semiconductor device having a DTI region.

Other issues and novel features will become apparent from the description of this specification and the accompanying drawings.

According to one embodiment, a semiconductor device includes a semiconductor substrate and an element isolation region. The semiconductor substrate includes a substrate region of a first conductivity type, a first semiconductor layer of a second conductivity type formed on the substrate region, and a second semiconductor layer of the first conductivity type formed on the first semiconductor layer. The element isolation region is formed in a trench that penetrates through the second semiconductor layer and the first semiconductor layer and reaches the substrate region. Each size of the plurality of first scallops formed at a side surface of the trench in the second semiconductor layer is larger than each size of the plurality of second scallops formed at a side surface of the trench in the first semiconductor layer.

According to one embodiment, the performance of the semiconductor device can be improved.

### BRIEF DESCRIPTION OF THE DRAWINGS

FIG. 1 is a main portion cross-sectional view of a semiconductor device of an embodiment.

FIG. 2 is a main portion cross-sectional view during a manufacturing step of the semiconductor device of the embodiment.

FIG. 3 is a main portion cross-sectional view during a manufacturing step of the semiconductor device following FIG. 2.

FIG. 4 is a main portion cross-sectional view during a manufacturing step of the semiconductor device following FIG. 3.

FIG. 5 is a main portion cross-sectional view during a manufacturing step of the semiconductor device following FIG. 4.

FIG. 6 is a main portion cross-sectional view during a manufacturing step of the semiconductor device following FIG. 5.

FIG. 7 is a main portion cross-sectional view during a manufacturing step of the semiconductor device following FIG. 6.

FIG. 8 is a main portion cross-sectional view during a manufacturing step of the semiconductor device following FIG. 7.

FIG. 9 is a main portion cross-sectional view during a manufacturing step of the semiconductor device following FIG. 8.

FIG. 10 is a main portion cross-sectional view during a manufacturing step of the semiconductor device following FIG. 9.

FIG. 11 is a main portion cross-sectional view during a manufacturing step of the semiconductor device following FIG. 10.

FIG. 12 is a main portion cross-sectional view during a manufacturing step of the semiconductor device following FIG. 11.

FIG. 13 is a process flow diagram showing part of the manufacturing step of the semiconductor device of the embodiment.

FIG. 14 is an explanatory diagram of a trench formation step.

FIG. 15 is an explanatory diagram of the trench formation step.

FIG. 16 is an explanatory diagram of the trench formation step.

FIG. 17 is an explanatory diagram of the trench formation step.

FIG. 18 is an explanatory diagram of the trench formation step.

FIG. 19 is an explanatory diagram of the trench formation step.

FIG. 20 is an explanatory diagram of the trench formation step.

FIG. 21 is an explanatory diagram of the trench formation step.

FIG. 22 is an explanatory diagram of the trench formation step.

FIG. 23 is an explanatory diagram of the trench formation step.

FIG. 24 is a partially enlarged cross-sectional view of a part of FIG. 7.

FIG. 25 is a partially enlarged cross-sectional view of a part of FIG. 1.

FIG. 26 is a main portion cross-sectional view during a manufacturing step of a semiconductor device of an examined example.

FIG. 27 is a main portion cross-sectional view during a manufacturing step of the semiconductor device of the examined example.

FIG. 28 is a main portion cross-sectional view during a manufacturing step of the semiconductor device of the examined example following FIG. 27.

FIG. 29 is a partially enlarged cross-sectional view of a part of FIG. 8.

FIG. 30 is a partially enlarged cross-sectional view of a part of FIG. 1.

FIG. 31 is a graph showing the correlation between the size of the scallops and the leakage current.

FIG. 32 is a graph showing the correlation between the size of the scallops and the sidewall resistance of the DTI region.

FIG. 33 is a plan view showing a test pattern for measuring the sidewall resistance of the DTI region.

### DETAILED DESCRIPTION

In the following embodiments, for convenience, when necessary, the description may be divided into a plurality of sections or embodiments, but unless specifically stated otherwise, they are not unrelated to each other, and one is related to the other as a part or all of a modified example, detail, supplementary explanation, etc. Also, in the following embodiments, when referring to the number of elements, etc. (including the number, numerical values, quantities, ranges, etc.), unless specifically stated otherwise and clearly limited to a specific number in principle, it is not limited to that specific number and may be more or less than the specific number. Furthermore, in the following embodiments, the constituent elements (including element steps, etc.) are not necessarily essential unless specifically stated otherwise and clearly considered essential in principle. Similarly, in the following embodiments, when referring to the shapes, positional relationships, etc. of components, unless specifically stated otherwise and clearly considered not so in principle, it is assumed to include those substantially approximate or similar to the shapes, etc. The same applies to the above numerical values and ranges.

Hereinafter, the embodiments will be described in detail with reference to the drawings. In all the drawings for explaining the embodiments, members having the same functions are denoted by the same reference numerals, and repetitive descriptions thereof are omitted. Also, in the following embodiments, descriptions of the same or similar parts will not be repeated in principle except when particularly necessary.

In the drawings used in the embodiments, hatching may be omitted even in the case of cross-sectional views to make the drawings easier to see. Also, even in the case of plan views, hatching may be used to make the drawing easier to see.

The term “plan view” corresponds to a view from a plane substantially parallel to the main surface or the back surface of a semiconductor substrate 1. The terms “bottom surface” and “lower surface” have the same meaning.

### Embodiment

### Structure of Semiconductor Device

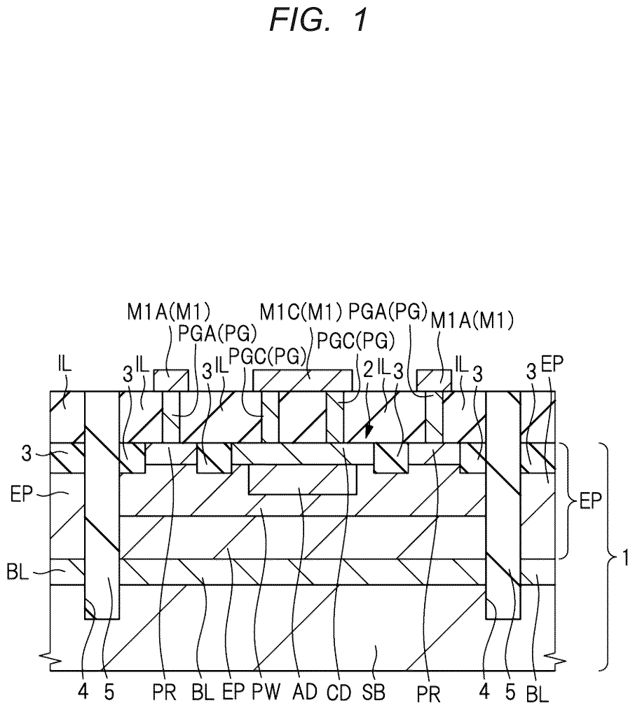

The semiconductor device of the embodiment will be described with reference to FIG. 1.

As shown in FIG. 1, the semiconductor device of the embodiment includes a semiconductor substrate 1, a Zener diode 2, an STI region 3, a DTI region 5, an insulating film IL, a plurality of plugs (contact plugs) PG, and a plurality of wirings M1.

As shown in FIG. 1, the semiconductor substrate 1 includes a p-type substrate region SB, an n-type buried layer BL formed on the p-type substrate region SB, and a p-type semiconductor layer EP formed on the n-type buried layer BL.

The p-type substrate region SB is made of p-type single crystal silicon doped with p-type impurities such as boron (B). A thickness of the p-type substrate region SB is almost uniform. The n-type buried layer BL is an n-type semiconductor layer. The n-type buried layer BL is made of n-type single crystal silicon formed on the p-type substrate region SB. A thickness of the n-type buried layer BL is almost uniform. The p-type semiconductor layer EP is made of p-type single crystal silicon formed on the n-type buried layer BL. The n-type buried layer BL and the p-type substrate region SB are in contact with each other. The p-type semiconductor layer EP and the n-type buried layer BL are in contact with each other.

The p-type substrate region SB may have a laminated structure formed of a p-type substrate body made of p-type single crystal silicon substrate and a p-type semiconductor layer formed on the p-type substrate body. In that case, a p-type impurity concentration of the p-type semiconductor layer on the p-type substrate body is lower than a p-type impurity concentration of the p-type substrate body, and a p-type impurity concentration of the p-type semiconductor layer EP on the n-type buried layer BL is lower than a p-type impurity concentration of the p-type substrate body.

The main surface of the semiconductor substrate 1 is synonymous with the main surface of the p-type semiconductor layer EP. Also, the back surface of the semiconductor substrate 1 is synonymous with the back surface of the p-type substrate region SB. The main surface of the semiconductor substrate 1 and the back surface of the semiconductor substrate 1 are located on opposite sides of each other.

The STI (Shallow Trench Isolation) region 3 is made of an insulating film buried in a trench formed in the semiconductor substrate 1. The DTI (Deep Trench Isolation) region 5 is made of an insulating film buried in a trench 4 formed in the insulating film IL on the semiconductor substrate 1 and in the semiconductor substrate 1. The bottom surface of DTI region 5 is in contact with the bottom surface of the trench 4, and the side surface of DTI region 5 is in contact with the side surface of the trench 4. Therefore, the depth of the bottom surface of the DTI region 5 is the same as the depth of the bottom surface of the trench 4. Both STI region 3 and DTI region 5 can be regarded as isolation regions.

The bottom surface of the STI region 3 is shallower than the bottom surface of the p-type semiconductor layer EP. The bottom surface of the DTI region 5 is deeper than the bottom surface of the STI region 3. The trench 4 and the DTI region 5 in the trench 4 penetrate through the insulating film IL, the STI region 3, the p-type semiconductor layer EP, and the n-type buried layer BL, and reach the p-type substrate region SB. The bottom surface of the trench 4 is deeper than the bottom surface of the n-type buried layer BL, and therefore, the bottom surface of the DTI region 5 is deeper than the bottom surface of the n-type buried layer BL. The trench 4 and the DTI region 5 in the trench 4 do not penetrate through the p-type substrate region SB. A part of the p-type substrate region SB exists under the bottom surface of the trench 4. DTI region 5 functions as an element isolation region.

In the case of FIG. 1, the trench 4 and the DTI region 5 penetrate through the insulating film IL, a part of the DTI region 5 is located in the insulating film IL and another part of the DTI region 5 is located in the semiconductor substrate 1. The trench 4 may be formed in the semiconductor substrate 1 without penetrating through the insulating film IL. In that case, the DTI region 5 is buried in the trench 4 in the semiconductor substrate 1, and the height position of the upper surface of the DTI region 5 is almost the same as the height position of the main surface of the semiconductor substrate 1.

The Zener diode 2 includes a p-type well region PW, a p-type semiconductor region AD, an n-type semiconductor region CD, and a p-type semiconductor region PR. The Zener diode 2 is surrounded by the DTI region 5 in plain view.

The p-type well region PW, the p-type semiconductor region AD, the n-type semiconductor region CD, and the p-type semiconductor region PR are formed in the p-type semiconductor layer EP. Specifically, the p-type well region PW is formed in the upper part of the p-type semiconductor layer EP, and the p-type semiconductor region AD, the n-type semiconductor region CD, and the p-type semiconductor region PR are formed in the p-type well region PW.

The n-type semiconductor region CD is in contact with the main surface of the semiconductor substrate 1 and is formed to a predetermined depth from the main surface of the semiconductor substrate 1. The n-type semiconductor region CD functions as the n-type cathode region of the Zener diode 2.

The p-type semiconductor region AD is formed under the n-type semiconductor region CD. The bottom surface of the p-type semiconductor region AD is shallower than the bottom surface of the p-type well region PW. A part of the p-type well region PW exists under the bottom surface of the p-type semiconductor region AD. A p-type impurity concentration of the p-type semiconductor region AD is higher than a p-type impurity concentration of the p-type well region PW. A part of the p-type semiconductor layer EP (p-type semiconductor region) exists under the bottom surface of the p-type well region PW. A p-type impurity concentration of the p-type well region PW is higher than a p-type impurity concentration of the p-type semiconductor layer EP under the p-type well region PW.

In a direction from the main surface to the back surface of the semiconductor substrate 1, the n-type semiconductor region CD and the p-type semiconductor region AD are in contact with each other, and a PN junction is formed between the n-type semiconductor region CD and the p-type semiconductor region AD.

A planar dimension (planar area) of the p-type semiconductor region AD is smaller than a planar dimension (planar area) of the n-type semiconductor region CD. The central part of the bottom surface of the n-type semiconductor region CD is in contact with the p-type semiconductor region AD, and the outer peripheral part of the bottom surface of the n-type semiconductor region CD is in contact with the p-type well region PW. Therefore, a PN junction is also formed between the n-type semiconductor region CD and the p-type well region PW. The side surface and the bottom surface of the p-type semiconductor region AD are covered by the p-type well region PW.

The p-type semiconductor region having the p-type semiconductor region AD and the p-type well region PW functions as the p-type anode region of the Zener diode 2. The PN junction surface formed at the interface between the n-type cathode region and the p-type anode region is configured by the PN junction surface between the n-type semiconductor region CD and the p-type semiconductor region AD, and the PN junction surface between the n-type semiconductor region CD and the p-type well region PW. In plan view, the PN junction surface between the n-type semiconductor region CD and the p-type semiconductor region AD is surrounded by the PN junction surface between the n-type semiconductor region CD and the p-type well region PW.

Since the p-type impurity concentration of the p-type semiconductor region AD is higher than the p-type impurity concentration of the p-type well region PW, the breakdown of the Zener diode 2 occurs at the PN junction between the n-type semiconductor region CD and the p-type semiconductor region AD. Therefore, the breakdown voltage of the Zener diode 2 is determined by the PN junction between the n-type semiconductor region CD and the p-type semiconductor region AD.

The p-type semiconductor region PR is in contact with the main surface of the semiconductor substrate 1 and is formed to a predetermined depth from the main surface of the semiconductor substrate 1. The depth of the bottom surface of the p-type semiconductor region PR is shallower than the depth of the bottom surface of the p-type well region PW. A part of the p-type well region PW exists under the bottom surface of the p-type semiconductor region PR. The p-type impurity concentration of the p-type semiconductor region PR is higher than the p-type impurity concentration of the p-type well region PW.

In plan view, the p-type semiconductor region PR does not overlap the n-type semiconductor region CD. For example, in plan view, the p-type semiconductor region PR surrounds the n-type semiconductor region CD. In plan view, the STI region 3 is disposed between the n-type semiconductor region CD and the p-type semiconductor region PR.

A back electrode (not shown) may be formed on the back surface of the semiconductor substrate 1. A ground potential can be supplied from the back electrode to the substrate region SB, for example.

Next, the structure over the semiconductor substrate 1 will be described.

The insulating film IL is formed on the main surface of the semiconductor substrate 1. The insulating film IL is formed of, for example, a laminated film of a silicon nitride film and a silicon oxide film. A plurality of contact holes are formed in the insulating film IL, and a plurality of conductive plugs PG are formed in the plurality of contact holes. The plurality of plugs PG include a plug PGA and a plug PGC. The plug PGA is disposed on the p-type semiconductor region PR and is electrically connected to the p-type semiconductor region PR. The plug PGC is disposed on the n-type semiconductor region CD and is electrically connected to the n-type semiconductor region CD.

A metal silicide layer (not shown) can also be formed on the n-type semiconductor region CD and the p-type semiconductor region PR. In that case, the plug PGC is electrically connected to the n-type semiconductor region CD via the metal silicide layer on the n-type semiconductor region CD. The plug PGA is electrically connected to the p-type semiconductor region PR via the metal silicide layer on the p-type semiconductor region PR.

A plurality of wirings M1 are formed on the insulating film IL. The plurality of wirings M1 include an anode wiring M1A and a cathode wiring M1C. The cathode wiring M1C is electrically connected to the n-type semiconductor region CD via the plug PGC. A cathode potential is supplied from the cathode wiring M1C to the n-type cathode region of the Zener diode 2 via the plug PGC. The anode wiring M1A is electrically connected to the p-type semiconductor region PR via the plug PGA and is further electrically connected to the p-type well region PW via the p-type semiconductor region PR. An anode potential is supplied from the anode wiring M1A to the p-type anode region of the Zener diode 2 via the plug PGA. The cathode wiring M1C and the anode wiring M1A are not connected to each other and are separated from each other.

The illustration and description of the structure formed above the insulation film IL and the plurality of wirings M1 are omitted.

The n-type cathode region and the p-type cathode region of the Zener diode 2 are formed in the p-type semiconductor layer EP surrounded by the DTI region 5 and the n-type buried layer BL. Therefore, the Zener diode 2 formed in the semiconductor substrate 1 can be electrically isolated from other semiconductor elements formed in the semiconductor substrate 1.

With the formation of the Zener diode 2 in the p-type semiconductor layer substrate EP surrounded by the DTI region 5 and the n-type buried layer BL, an NPN parasitic transistor and a PNP parasitic transistor can be formed in the semiconductor substrate SB. The NPN parasitic transistor has an n-type emitter region formed of the n-type semiconductor region CD, a p-type base region formed of the p-type semiconductor region AD, the p-type semiconductor region PR, and the p-type well region PW, and an n-type collector region formed of the n-type buried layer BL. The PNP parasitic transistor has a p-type emitter region formed of the p-type substrate region SB, an n-type base region formed of the n-type buried layer BL, and a p-type collector region formed of the p-type semiconductor region AD, the p-type semiconductor region PR, and the p-type well region PW. A parasitic thyristor can be formed by the NPN parasitic transistor and the PNP parasitic transistor.

The case where the Zener diode 2 is formed as a semiconductor element in the p-type semiconductor layer EP surrounded by the DTI region 5 and the n-type buried layer BL has been described. There may also be cases where semiconductor elements other than the Zener diode 2 are formed in the p-type semiconductor layer EP surrounded by the DTI region 5 and the n-type buried layer BL.

### Manufacturing Step of Semiconductor Device

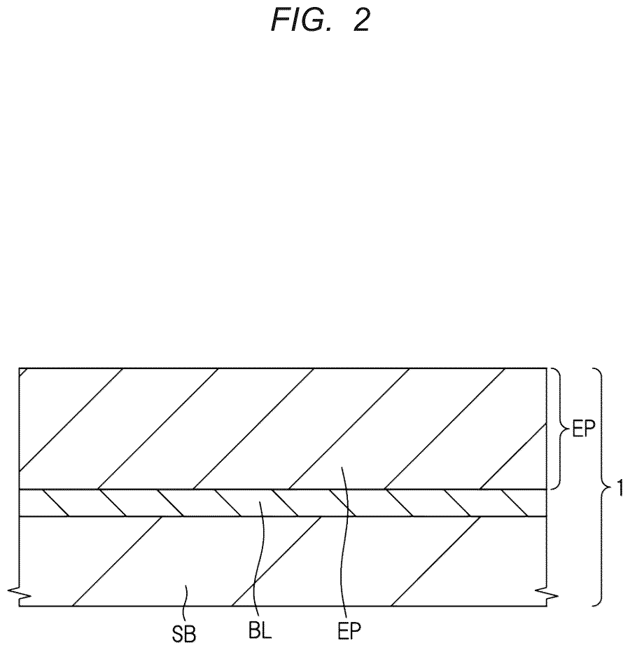

As shown in FIG. 2, the semiconductor substrate 1 having the p-type substrate region SB, the n-type buried layer BL on the p-type substrate region SB, and the p-type semiconductor layer EP on the n-type buried layer BL is prepared. The thickness of the p-type semiconductor layer EP is, for example, 3 micrometers or more and 6 micrometers or less. The thickness of the n-type buried layer BL is, for example, 4 micrometers or more and 7 micrometers or less.

For example, the n-type buried layer BL can be formed by ion implantation in the surface layer portion of a p-type silicon substrate, and then the p-type semiconductor layer EP can be formed on the n-type buried layer BL using an epitaxial growth method. In this case, the p-type silicon substrate under the n-type buried layer BL corresponds to the p-type substrate region SB. An epitaxial wafer can also be used instead of the above-mentioned p-type silicon substrate. The epitaxial wafer has a p-type silicon substrate body, and a p-type semiconductor layer formed on the p-type silicon substrate body.

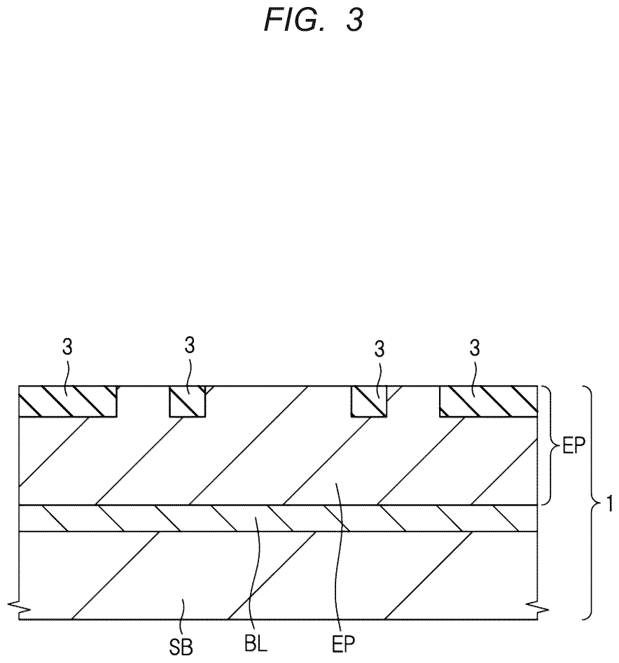

Next, as shown in FIG. 3, the STI region 3 is formed using the STI method.

After forming a trench at the main surface of the semiconductor substrate 1, an insulating film made of a silicon oxide film, or the like is formed on the main surface of the semiconductor substrate 1 so as to fill the trench. Then, the insulating film disposed outside the trench is removed using a method such as CMP (Chemical Mechanical Polishing). This allows the formation of the STI region 3 formed of the insulating film buried in the trench.

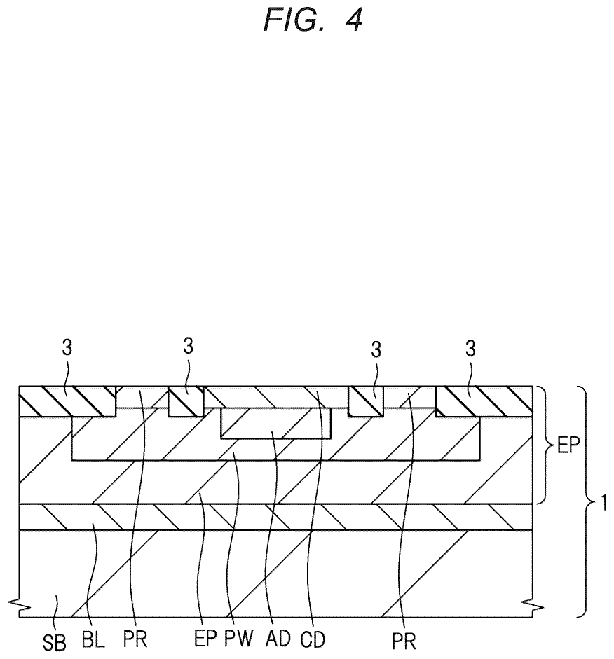

Next, as shown in FIG. 4, the p-type well region PW, the p-type semiconductor region AD, the n-type semiconductor region CD, and the p-type semiconductor region PR are formed in the p-type semiconductor layer EP using ion implantation or the like. The formation order of the p-type well region PW, the p-type semiconductor region AD, the n-type semiconductor region CD, and the p-type semiconductor region PR can be selected as needed.

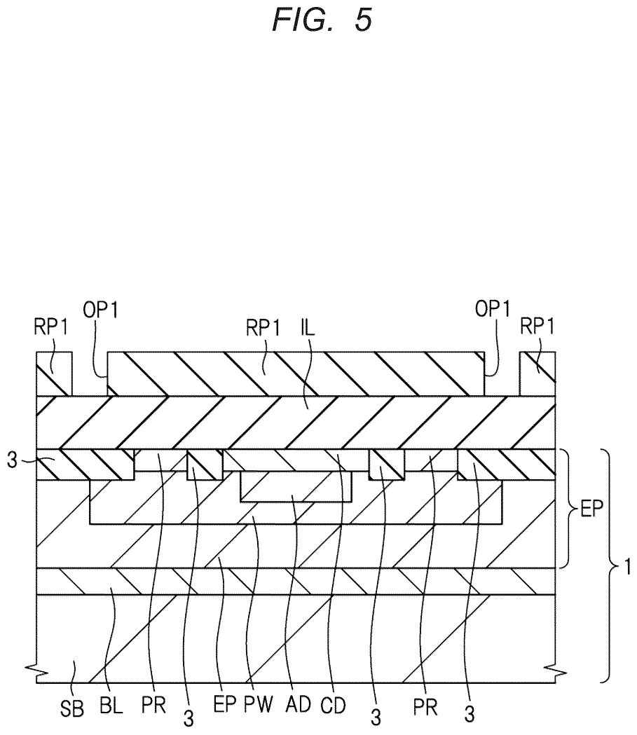

Next, as shown in FIG. 5, the insulating film IL is formed on the main surface of the semiconductor substrate 1 using a method such as CVD (Chemical Vapor Deposition). After forming the insulating film IL, the upper surface of the insulating film IL can be polished and flattened using a method such as CMP.

Next, as shown in FIG. 5, a photoresist pattern RP1 is formed on the insulating film IL using photolithography technology.

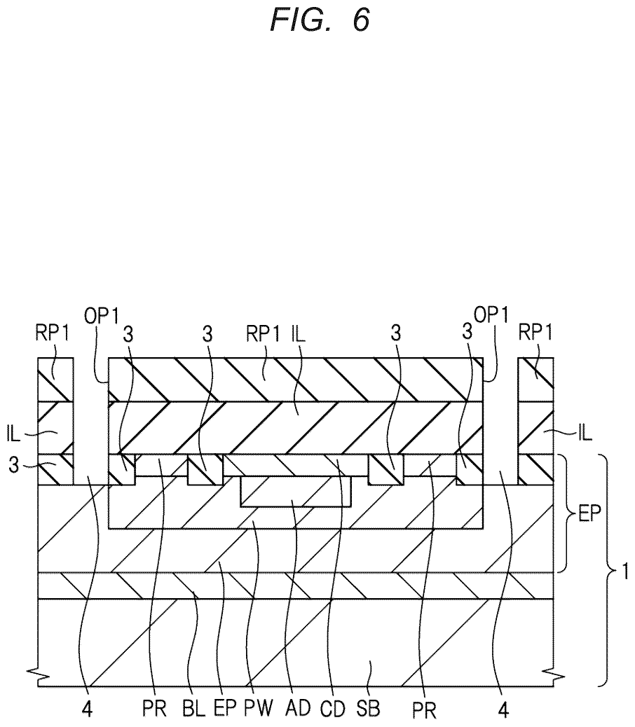

Next, as shown in FIG. 6, the trench 4 is formed by etching the insulating film IL and the STI region 3 using the photoresist pattern RP1 as an etching mask. This etching step is referred to as the etching step of FIG. 6.

In the etching step of FIG. 6, the trench 4 is formed to penetrate through the insulating film IL and the STI region 3, and the semiconductor substrate 1 (p-type semiconductor layer EP) functions as an etching stopper. Therefore, the etching step of FIG. 6 includes a step of etching the insulating film IL and a step of etching the STI region 3. The step of etching the STI region 3 is performed under conditions where the etching rate of the semiconductor substrate 1 (p-type semiconductor layer EP) is lower than the etching rate of the STI region 3. As a result, in the etching step of FIG. 6, the semiconductor substrate 1 (p-type semiconductor layer EP) is hardly etched. At the end of the etching step of FIG. 6, the side surfaces of the trench 4 are configured by the insulating film IL and the STI region 3, the bottom surface of the trench 4 is configured by the semiconductor substrate 1 (p-type semiconductor layer EP), and the depth of the bottom surface of the trench 4 is almost the same as the depth of the surface of the semiconductor substrate 1 (p-type semiconductor layer EP) under the STI region 3. The side surfaces of the trench 4 align with the side surfaces of an opening OP1 of the photoresist pattern RP1.

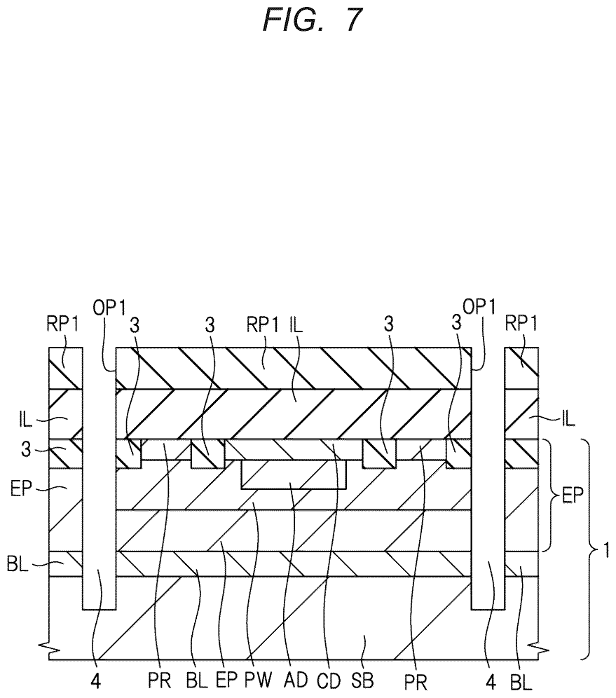

Next, as shown in FIG. 7, using the photoresist pattern RP1 as an etching mask, the semiconductor substrate 1 (p-type semiconductor layer EP, n-type buried layer BL, and p-type substrate region SB) exposed from the trench 4 is etched to deepen the trench 4. This etching step is referred to as the etching step of FIG. 7.

By performing the etching step of FIG. 7, the trench 4 penetrates through the p-type semiconductor layer EP and the n-type buried layer BL to reach the p-type substrate region SB. At the end of the etching step of FIG. 7, the trench 4 penetrates through the insulating film IL, the STI region 3, the p-type semiconductor layer EP, and the n-type buried layer BL to reach the p-type substrate region SB, and the bottom surface of the trench 4 is deeper than the bottom surface of the n-type buried layer BL. However, the trench 4 does not penetrate through the p-type substrate region SB. The bottom surface of the trench 4 is located in the middle of the thickness of the p-type substrate region SB. The depth from the bottom surface of the n-type buried layer BL to the bottom surface of the trench 4 is, for example, about 6 micrometers or more and about 9 micrometers or less.

The etching step of FIG. 7 will be described in more detail later.

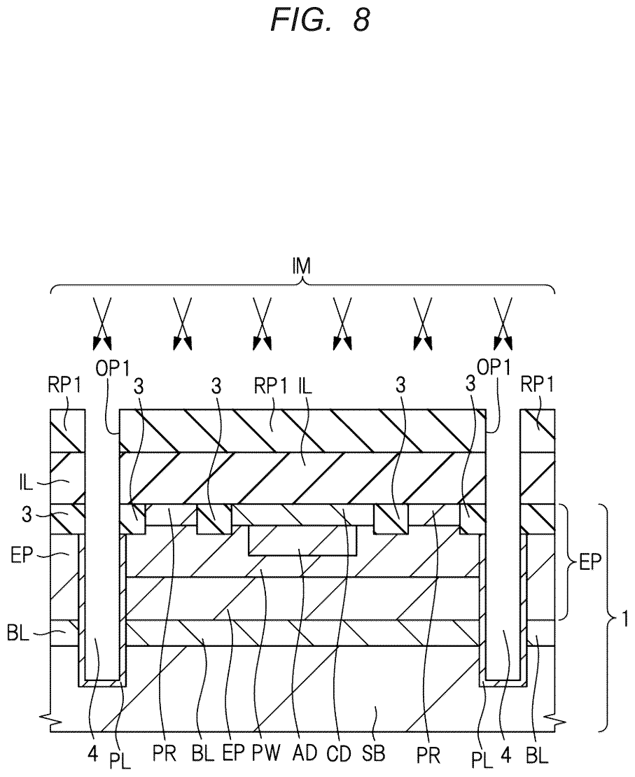

Next, as shown in FIG. 8, ion implantation of p-type impurities is performed on the semiconductor substrate 1 exposed from the trench 4. This ion implantation is schematically shown as ion implantation IM in FIG. 8.

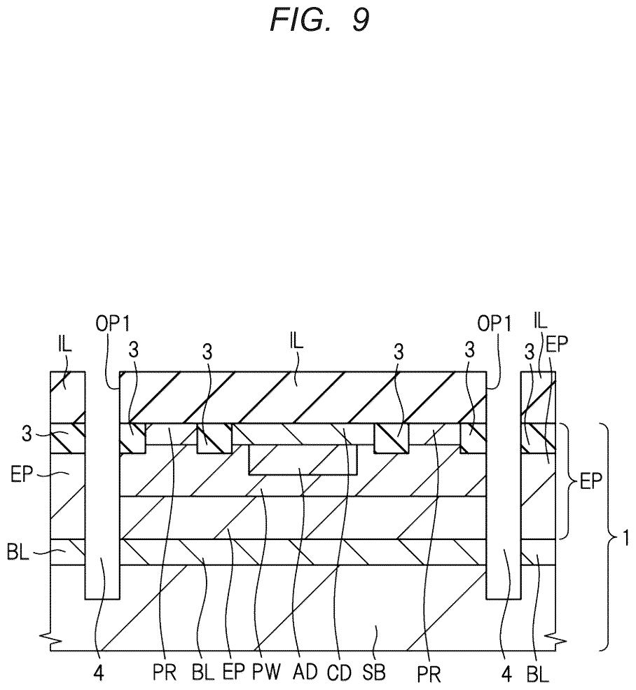

As the ion implantation IM, oblique ion implantation of p-type impurities is performed. In the case of oblique ion implantation, the incident direction of the impurity ions is inclined with respect to the normal direction of the main surface of the semiconductor substrate. A region PL where p-type impurities are implanted by the ion implantation IM in the semiconductor substrate 1 is shown in FIG. 9. By the ion implantation IM, p-type impurities are implanted into the semiconductor substrate 1 from the bottom and side surfaces of the trench 4. Therefore, the region PL is formed along the bottom and side surfaces of the trench 4 in the semiconductor substrate 1.

Next, as shown in FIG. 9, the photoresist pattern RP1 is removed. Note that the illustration of the region PL is omitted from FIG. 9 to FIG. 12.

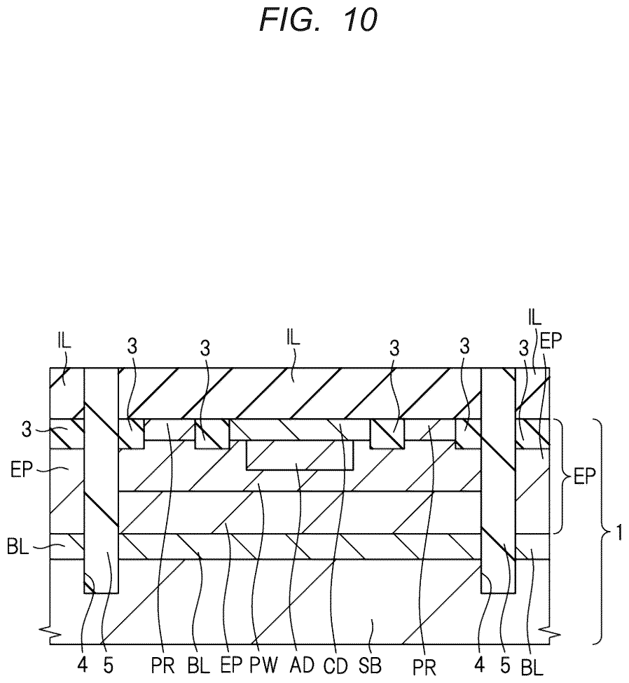

Next, as shown in FIG. 10, the DTI region 5 is formed in the trench 4.

After forming the trench 4, an insulating film made of silicon oxide film, or the like is formed on the insulating film IL to fill the trench 4. Thereafter, the insulating film disposed outside the trench 4 is removed using a CMP method or the like. This allows the formation of the DTI region 5 made of the insulating film buried in the trench 4. A void may be formed in the DTI region 5. Although the case where the insulating film disposed outside the trench 4 is removed using a CMP method or the like has been described, this step may be omitted. In that case, the insulation film integrally formed with the DTI region 5 remains on the insulating film IL.

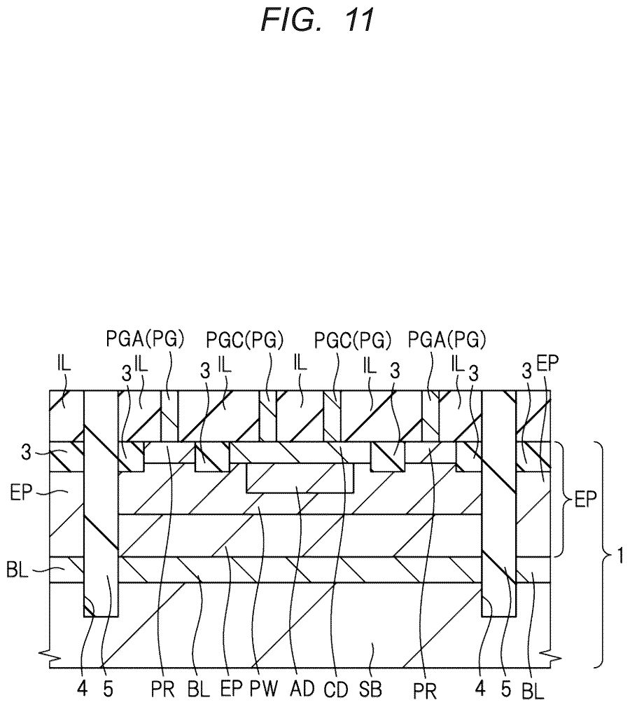

Next, as shown in FIG. 11, by etching the insulating film IL using a photoresist pattern (not shown) formed on the insulating film IL as an etching mask, a plurality of contact holes penetrating through the insulating film IL are formed. Thereafter, a plurality of conductive plugs PG are respectively formed in the plurality of contact holes.

For example, a barrier conductor film is formed on the bottom surface of the contact hole, on the side surface of the contact hole, and on the upper surface of the insulating film IL. Next, a main conductor film made of tungsten, or the like is formed on the barrier conductor film to fill the contact hole. Thereafter, the main conductor film and the barrier conductor film disposed outside the contact hole are removed by a CMP method or the like. This allows the formation of the plurality of plugs PG.

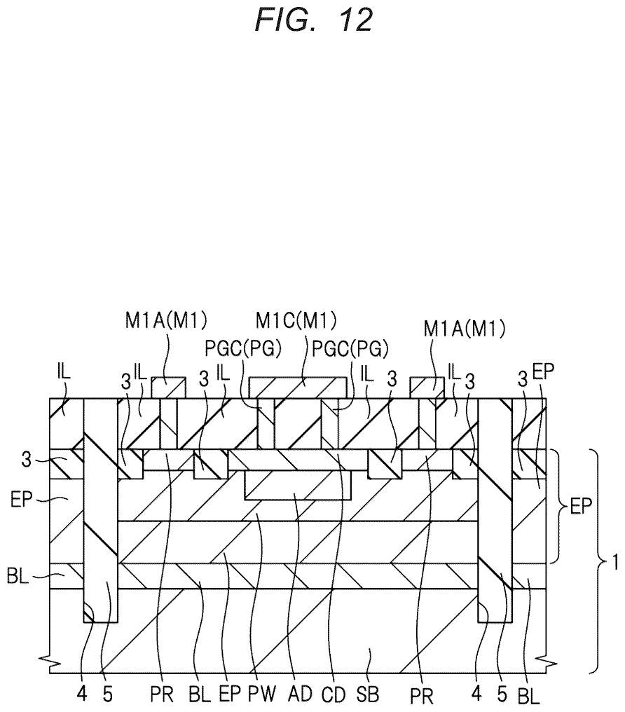

Next, as shown in FIG. 12, the plurality of wirings M1 are formed on the insulating film IL. For example, a conductive film is formed on the insulating film IL. Thereafter, by patterning the conductive film using photolithography and etching techniques, the plurality of wirings M1 made of the conductive film can be formed. Although aluminum wiring is preferable for the plurality of wirings M1, wiring using other metal materials, such as tungsten wiring, can also be applied. Additionally, copper wiring formed using damascene technology can also be applied as the plurality of wirings M1.

The plurality of wirings M1 includes the anode wiring M1A and the cathode wiring M1C.

The illustration and description of the step of forming an insulating film and wiring on the plurality of wirings M1 are omitted.

### Trench Formation Step

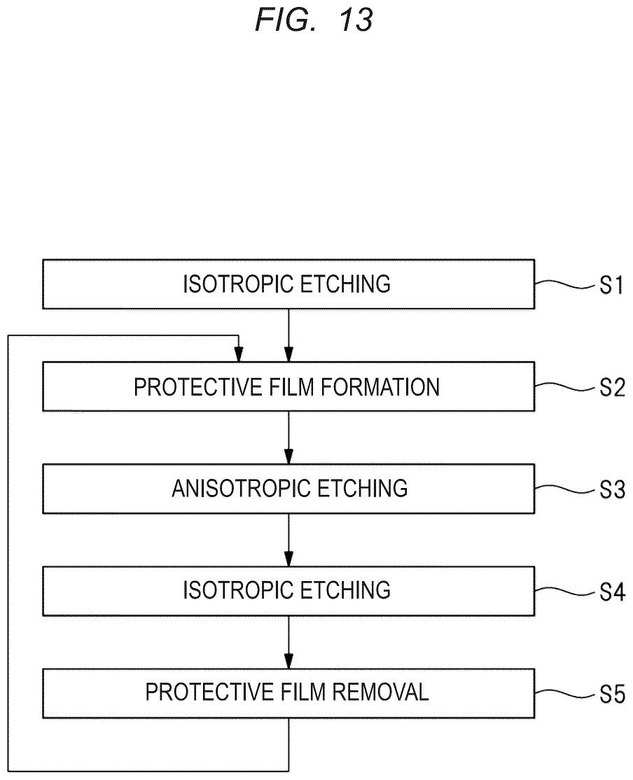

The trench 4 formation step will be further described. FIG. 13 shows a specific flow of the etching step of FIG. 7.

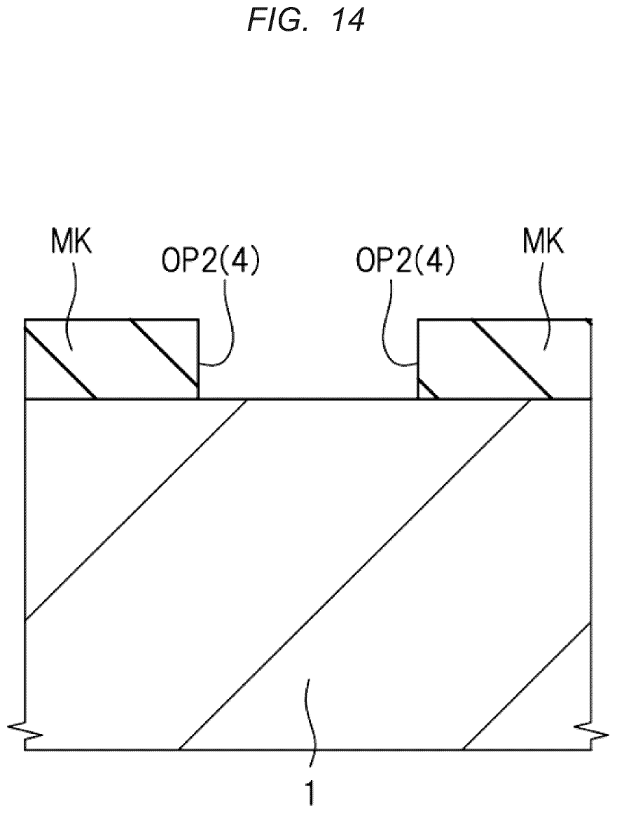

FIG. 14 is a cross-sectional view showing the state after the etching step of FIG. 6 is completed and before the etching step of FIG. 7 is performed. In FIG. 14, a laminated structure formed of the STI region 3, the insulation film IL on the STI region 3, and the photoresist pattern RP1 on the insulating film IL is schematically shown as a mask layer MK. An opening OP2 of the mask layer MK shown in FIG. 14 is formed of the opening OP1 of the photoresist pattern RP1 and the trench 4 shown in FIG. 6. The side surfaces of the opening OP2 of the mask layer MK shown in FIG. 14 are configured by the side surfaces of the trench 4 shown in FIG. 6 and the side surfaces of the opening OP1 of the photoresist pattern RP1. The opening OP2 of the mask layer MK penetrates through the mask layer MK. The semiconductor substrate 1 exposed from the opening OP2 of the mask layer MK corresponds to the semiconductor substrate 1 exposed from the trench 4.

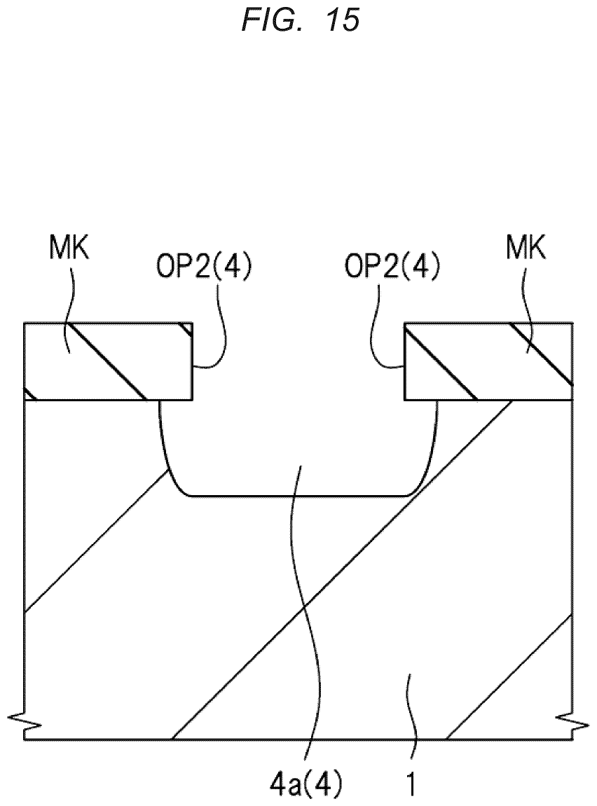

After the etching step of FIG. 6, as shown in FIG. 15, using the mask layer MK as an etching mask, the semiconductor substrate 1 exposed from the opening OP2 of the mask layer MK (and thus the semiconductor substrate 1 exposed from the trench 4) is isotropically etched (step S1 of FIG. 13).

In the isotropic etching step of step S1, it is preferable to use isotropic dry etching. Isotropic dry etching can be performed using, for example, fluorine radicals. In step S1, SF₆ gas can be preferably used as the etching gas. The isotropic etching step of step S1 is performed under conditions where the etching rate of the semiconductor substrate 1 is greater than the etching rate of the mask layer MK.

In the isotropic etching step of step S1, not only etching along the depth direction but also the side etching occurs. The depth direction is orthogonal to the main surface of the semiconductor substrate 1 and is directed from the main surface to the back surface of the semiconductor substrate 1. The isotropic etching step of step S1 generates a removal region 4a in the semiconductor substrate 1. The removal region 4a is, for example, a shell-shaped or bowl-shaped depression. The removal region 4a configures a part of the trench 4. The bottom surface of the removal region 4a corresponds to the bottom surface of the trench 4. In plan view, the planar dimension (plan area) of the removal region 4a is larger than the planar dimension of the opening OP2 of the mask layer MK.

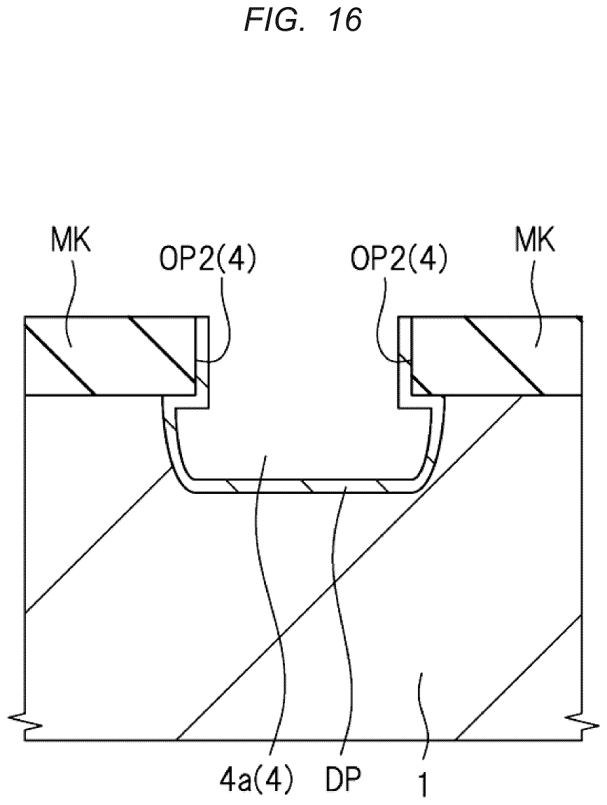

Next, as shown in FIG. 16, a protective film DP is formed (step S2 of FIG. 13).

In the protective film formation step of step S2, the protective film DP is formed on the upper surface of the mask layer MK, on the side surface of the opening OP2 of the mask layer MK, and on the surface of the semiconductor substrate 1 exposed from the trench 4. Therefore, the protective film DP is formed on the side and bottom surfaces of the trench 4. In the protective film formation step of step S2, the protective film DP can be formed using, for example, fluorocarbon radicals. For example, the protective film DP can be formed (deposited) using C₄F₈ gas.

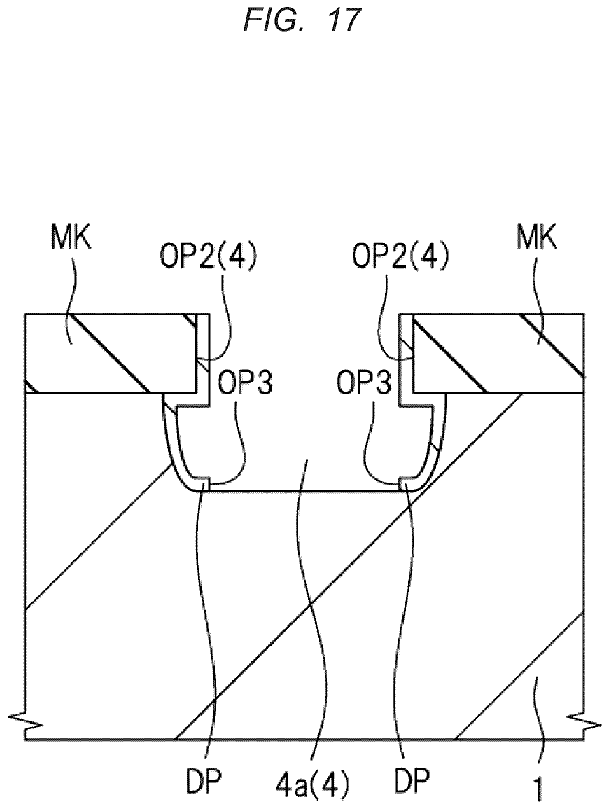

Next, as shown in FIG. 17, using the mask layer MK as an etching mask, the protective film DP is anisotropically etched (step S3 of FIG. 13).

In the anisotropic etching step of step S3, anisotropic dry etching is used. Anisotropic dry etching can be performed using, for example, fluorine-based ions. In the anisotropic etching step of step S3, SF₆ gas can be preferably used as the etching gas.

In the anisotropic etching step of step S3, the portion of the protective film DP on the bottom surface of the trench 4 that overlaps the opening OP2 of the mask layer MK in plan view is removed, thereby forming an opening OP3 in the protective film DP. Through the opening OP3 of the protective film DP, the semiconductor substrate 1 is exposed. The opening OP3 of the protective film DP is formed on the bottom surface of the trench 4. In plan view, the planar dimension (plan area) of the removal region of the protective film DP is approximately the same as or slightly smaller than the planar dimension of the opening OP2 of the mask layer MK. Therefore, in plan view, the planar dimension of the opening OP3 of the protective film DP is smaller than the planar dimension of the removal region 4a.

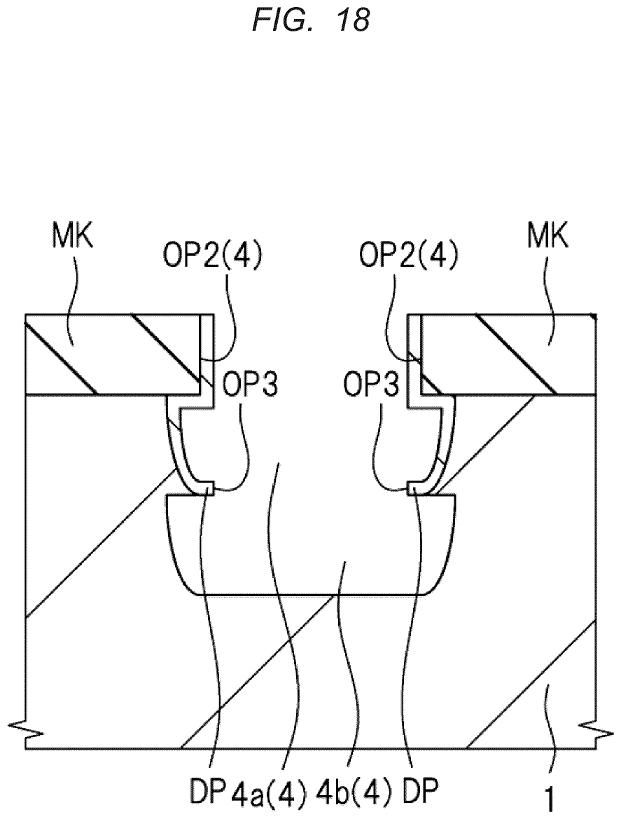

Next, as shown in FIG. 18, using the mask layer MK and the protective film DP as an etching mask, the semiconductor substrate 1 exposed from the opening OP3 of the protective film DP is isotropically etched (step S4 in FIG. 13).

In the isotropic etching step of step S4, it is preferable to use isotropic dry etching. Isotropic dry etching can be performed using, for example, fluorine radicals. In the isotropic etching step of step S4, SF₆ gas can be preferably used as the etching gas. The isotropic etching step of step S4 is carried out under conditions where the etching rate of the semiconductor substrate 1 is greater than the etching rate of the protective film DP.

In the isotropic etching step of step S4, since the semiconductor substrate 1 exposed from the opening OP3 of the protective film DP is isotropically etched, not only etching along the depth direction but also side etching occurs in the semiconductor substrate 1. The isotropic etching step of step S4 results in the formation of a removal region 4b in the semiconductor substrate 1. The removal region 4b is located under the removal region 4a. The removal region 4b is, for example, a shell-shaped or bowl-shaped depression. The removal region 4b configures a part of the trench 4. The bottom surface of the removal region 4b corresponds to the bottom surface of the trench 4. In plan view, the planar dimension of the removal region 4b is larger than the planar dimension of the opening OP3 of the protective film DP and also larger than the planar dimension of the opening OP2 of the mask layer MK.

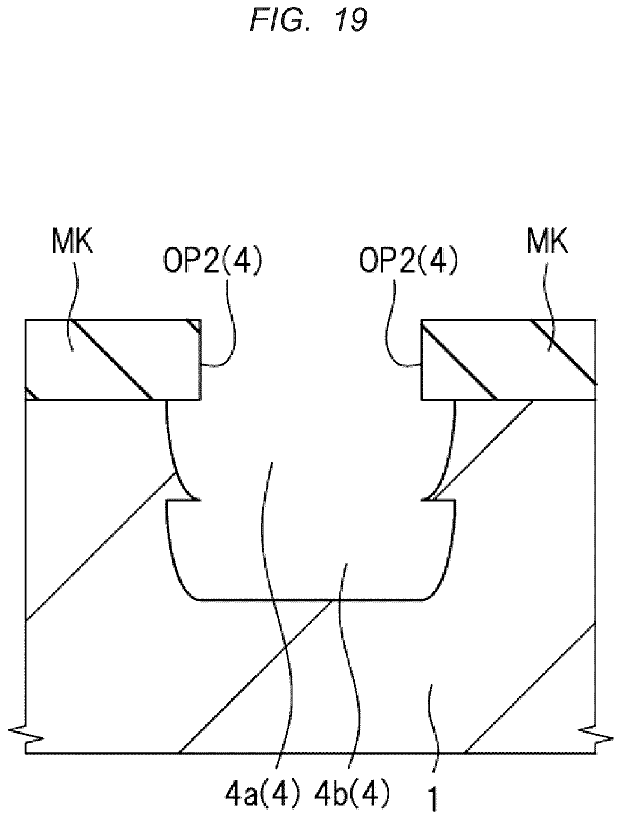

Next, as shown in FIG. 19, the protective film DP is removed (step S5 in FIG. 13).

Thereafter, the protective film formation step of step S2, the anisotropic etching step of step S3, the isotropic etching step of step S4, and the protective film removal step of step S5 are repeated as one cycle for plurality of cycles.

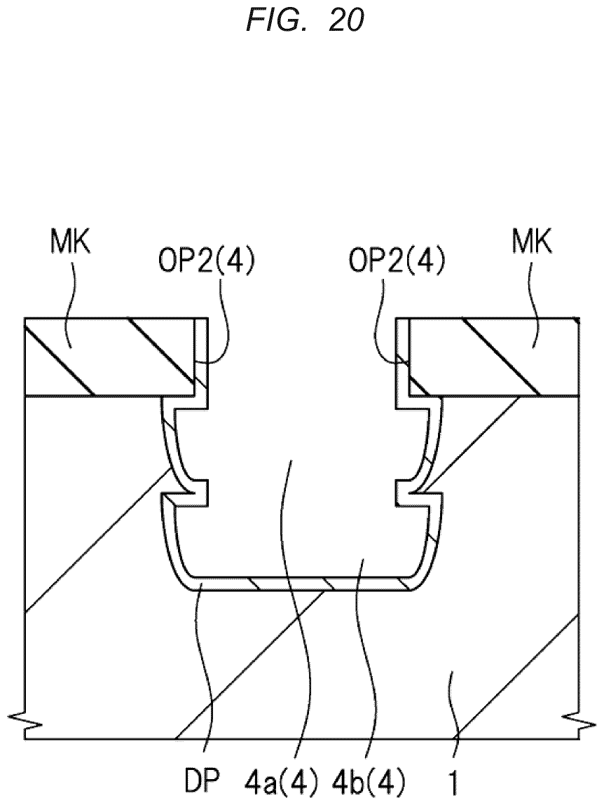

That is, as shown in FIG. 20, the protective film DP is formed (step S2 in FIG. 13). The protective film DP is formed on the side and bottom surfaces of the trench 4.

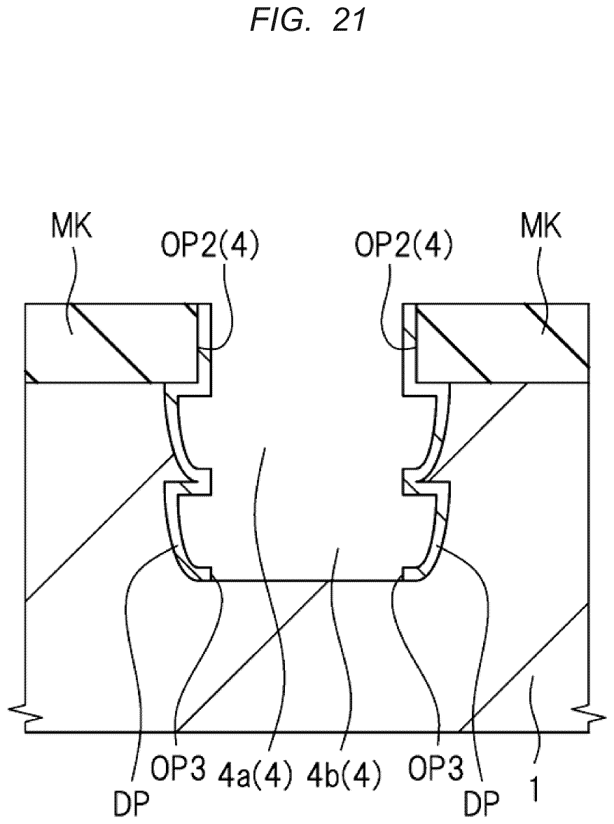

Next, as shown in FIG. 21, using the mask layer MK as an etching mask, the protective film DP is anisotropically etched (step S3 in FIG. 13). By anisotropic etching step of step S3, the opening OP3 is formed in the protective film DP, and the semiconductor substrate 1 is exposed from the opening OP3 of the protective film DP. The opening OP3 of the protective film DP is formed on the bottom surface of the trench 4.

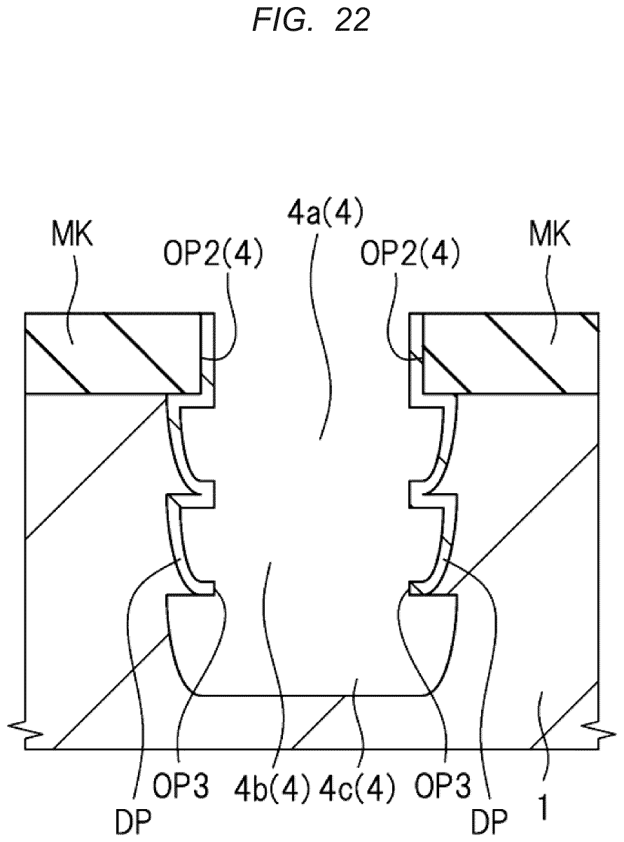

Next, as shown in FIG. 22, using the mask layer MK and the protective film DP as an etching mask, the semiconductor substrate 1 exposed from the opening OP3 of the protective film DP is isotropically etched (step S4 in FIG. 13). The isotropic etching step of step S4 results in the formation of a removal region 4c in the semiconductor substrate 1. The removal region 4c is located under the removal region 4b. The removal region 4c is, for example, a shell-shaped or bowl-shaped depression. The removal region 4c configures a part of trench 4, and the bottom surface of the removal region 4c corresponds to the bottom surface of trench 4.

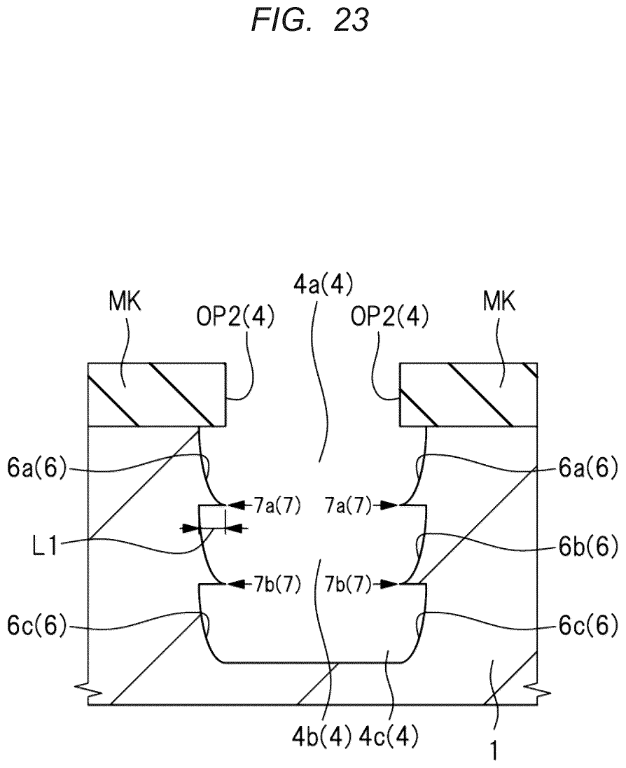

Next, as shown in FIG. 23, the protective film DP is removed (step S5 in FIG. 13).

Each time steps S2, S3, S4, and S5 are repeated, the depth of the trench 4 gradually increases. Steps S2, S3, S4, and S5 are repeated until the trench 4 penetrates through the p-type semiconductor layer EP and the n-type buried layer BL to reach the p-type substrate region SB.

### Trench 4 and DTI Region 5

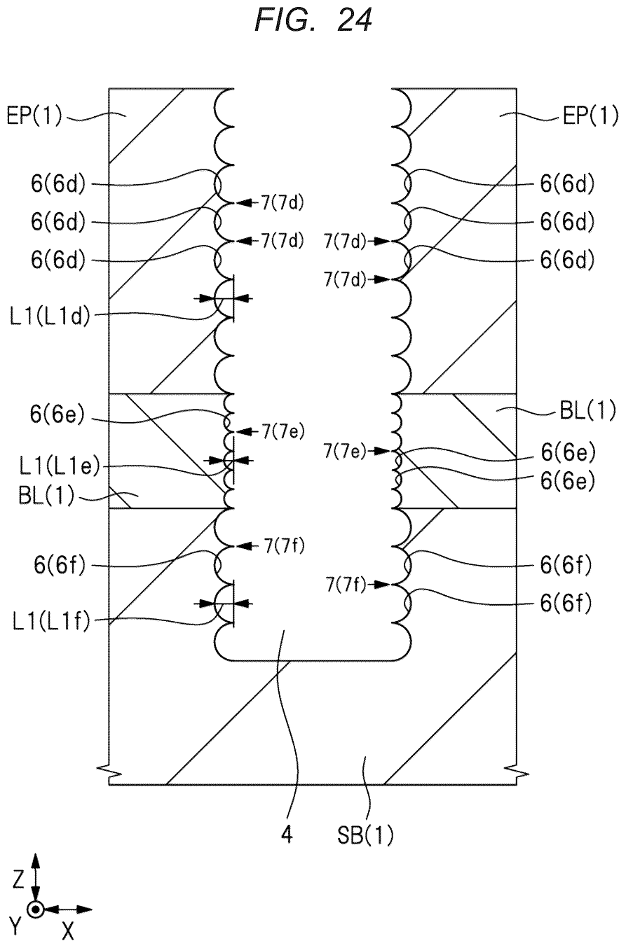

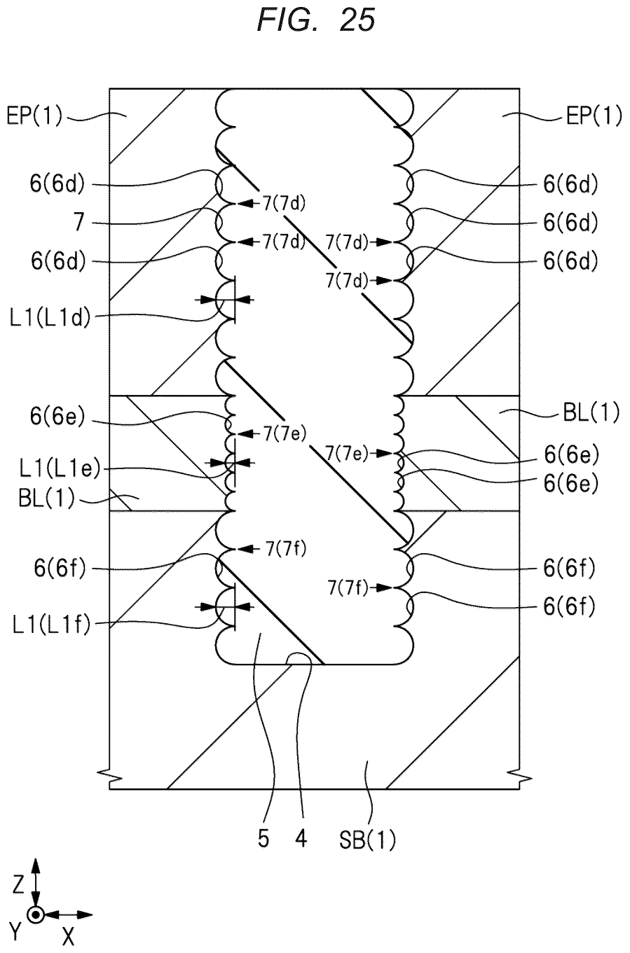

FIGS. 24 and 25 show the X, Y, and Z directions. The X, Y, and Z directions are orthogonal to each other. The X and Y directions are approximately parallel to the main surface of the semiconductor substrate, and the Z direction is approximately orthogonal to the main surface of the semiconductor substrate. Therefore, the Z direction is parallel to the depth direction. FIGS. 24 and 25 show a cross-section parallel to the X and Z directions and orthogonal to the Y direction. The trench 4 shown in FIG. 24 extends in the Y direction. The X direction is the width direction of the trench 4 shown in FIG. 24.

In the semiconductor substrate 1, the trench 4 is formed by the connection of plurality of removal regions of the semiconductor substrate 1, such as the aforementioned removal regions 4a, 4b, and 4c, in the Z direction. Therefore, as shown in FIGS. 24 and 25, a plurality of scallops 6 are formed on the side surface of the trench 4 in the semiconductor substrate 1. The plurality of scallops 6 are connected in the Z direction.

The scallop 6 has, for example, a shell-shaped or bowl-shaped curved surface shape or an inverted taper shape, and a protrusion (convex portion) 7 exists at the boundary between the plurality of scallops 6. The protrusion 7 is a portion where the side surface of the trench 4 locally protrudes inward. Each protrusion 7 extends in a direction approximately orthogonal (horizontal direction) to the Z direction along the side surface of the trench 4. The protrusions 7 shown in FIGS. 24 and 25 protrude in the X direction and extend in the Y direction along the side surface of the trench 4. Since the plurality of scallops 6 are connected in the Z direction, the plurality of protrusions 7 extending in the Y direction along the side surface of the trench 4 are periodically arranged in the Z direction.

The reason the plurality of scallops 6 are formed is that the etching of the semiconductor substrate 1 when forming the trench 4 is mainly performed by the isotropic etching step of step S4. One scallop 6 is formed by the removal region of the semiconductor substrate 1 generated in one isotropic etching step of step S4. For example, as shown in FIG. 23, a scallop 6a is formed by the side surface of the removal region 4a, a scallop 6b is formed under the scallop 6a by the side surface of the removal region 4b, and a scallop 6c is formed under the scallop 6b by the side surface of the removal region 4c. A protrusion 7a is formed at the boundary between the scallop 6a and the scallop 6b, and a protrusion 7b is formed at the boundary between the scallop 6b and the scallop 6c. The number of scallops 6 corresponding to the number of cycles of repeating steps S2, S3, S4, and S5 is stacked in the Z direction.

FIGS. 23, 24, and 25 show the size L1 of the scallop 6. The size L1 of the scallop 6 corresponds to the distance between the tip of the protrusion 7 and the bottom of the scallop 6 in the width direction (X direction) of the trench 4. The bottom of each scallop 6 corresponds to the farthest part from the center of the trench 4 in the width direction (X direction) of the trench 4. Therefore, the size L1 of the scallop 6 indicates the size of the unevenness (step) of the side surface of the trench 4 caused by the scallop 6. A larger size L1 of the scallop 6 indicates a larger unevenness (step) caused by the scallop 6. The size L1 of the scallop 6 can be controlled by factors such as the etching amount in the isotropic etching step of step S4. The larger the etching amount of the semiconductor substrate 1 in the isotropic etching step of step S4 (etching amount in the Z direction), the larger the size L1 of the scallop 6.

The trench 4 penetrates through the p-type semiconductor layer EP and the n-type buried layer BL to reach the p-type substrate region SB. Therefore, the side surface of the trench 4 includes the side surface of the trench 4 formed in the p-type semiconductor layer EP, the side surface of the trench 4 formed in the n-type buried layer BL, and the side surface of the trench 4 formed in the p-type substrate region SB. The side surface of the trench 4 formed in the p-type semiconductor layer EP is continuous with the side surface of the trench 4 formed in the n-type buried layer BL, and the side surface of the trench 4 formed in the n-type buried layer BL is continuous with the side surface of the trench 4 formed in the p-type substrate region SB.

Here, the scallop 6 formed on the side surface of the trench 4 in the p-type semiconductor layer EP is referred to as a scallop 6d, the scallop 6 formed on the side surface of the trench 4 in the n-type buried layer BL is referred to as a scallop 6e, and the scallop 6 formed on the side surface of the trench 4 in the p-type substrate region SB is referred to as a scallop 6f. The size L1 of the scallop 6d is referred to as the size L1d, the size L1 of the scallop 6e is referred to as the size L1e, and the size L1 of the scallop 6f is referred to as the size L1f. The protrusion 7 formed on the side surface of the trench 4 in the p-type semiconductor layer EP is referred to as a protrusion 7d, the protrusion 7 formed on the side surface of the trench 4 in the n-type buried layer BL is referred to as a protrusion 7e, and the protrusion 7 formed on the side surface of the trench 4 in the p-type substrate region SB is referred to as a protrusion 7f.

It is preferable that the size L1d of the scallop 6d is larger than the size L1e of the scallop 6e. It is preferable that the size L1f of the scallop 6f is larger than the size L1e of the scallop 6e. The reason for this will be explained in detail later.

The scallop 6d is formed by isotropically etching the p-type semiconductor layer EP in the isotropic etching step of step S4. The scallop 6e is formed by isotropically etching the n-type buried layer BL in the isotropic etching step of step S4. The scallop 6f is formed by isotropically etching the p-type substrate region SB in the isotropic etching step of step S4.

### Background of Study

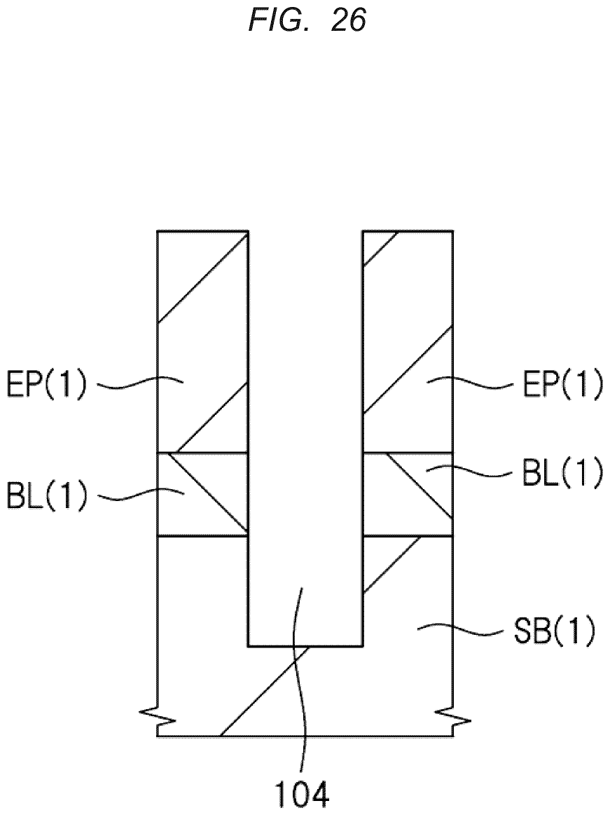

The examined example considered by the inventor of the present invention will be described with reference to FIGS. 26 to 28.

FIG. 26 shows a state where a trench 104 for a DTI region is formed in the semiconductor substrate 1. The trench 104 is formed by anisotropically etching the p-type semiconductor layer EP, the n-type buried layer BL, and the p-type substrate region SB. Therefore, the above-mentioned scallop 6 is not formed on the side surface of the trench 104.

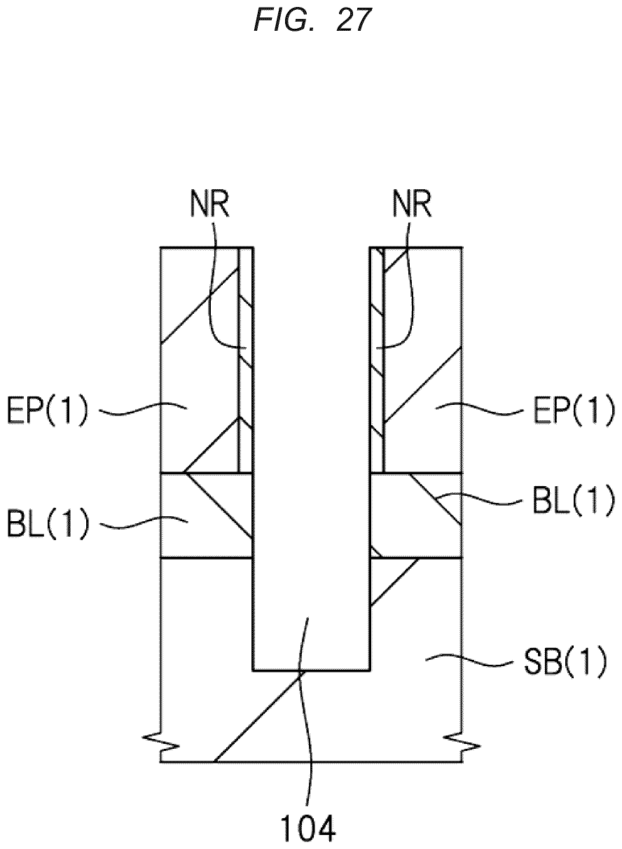

In the step of forming the trench 104, when the n-type buried layer BL is being etched, there is a risk that etching residues containing n-type impurities may adhere to the side surface of the trench 104 in the p-type semiconductor layer EP. As a result, due to the etching residues containing n-type impurities, there is a risk that an n-type semiconductor region NR may be formed in the p-type semiconductor layer EP along the side surface of the trench 104, as shown in FIG. 27.

If the n-type semiconductor region NR is formed in the p-type semiconductor layer EP along the side surface of the trench 104, it may adversely affect the operation of semiconductor devices (such as the aforementioned Zener diode 2) formed in the p-type semiconductor layer EP. This is because the n-type semiconductor region NR may configure part of a parasitic transistor and act to promote the operation of the parasitic transistor. Therefore, to improve the performance of the semiconductor device, it is desirable to prevent the formation of unnecessary n-type semiconductor region NR in the p-type semiconductor layer EP.

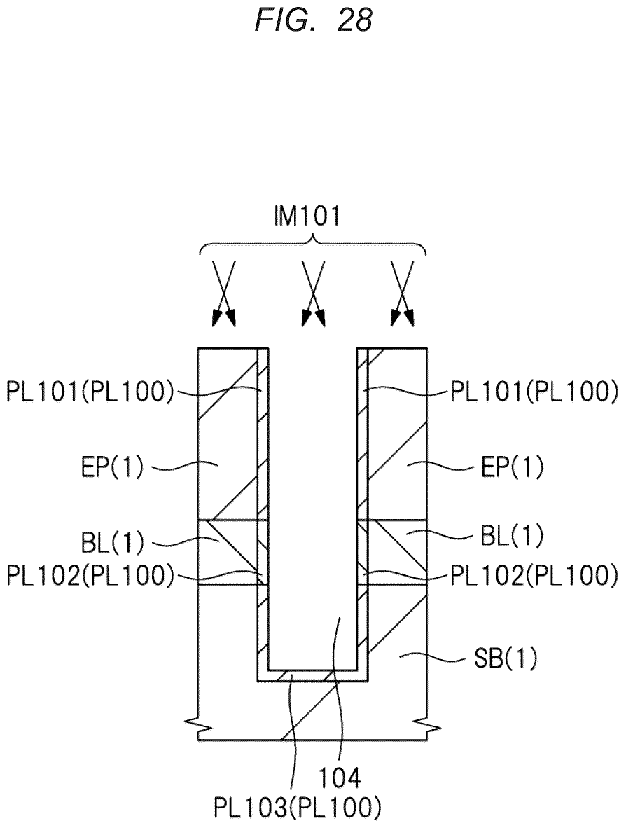

Thus, after forming the trench 104, as shown in FIG. 28, the implantation of p-type impurities is performed into the semiconductor substrate 1 exposed from the trench 104. This ion implantation is schematically shown as ion implantation IM101 in FIG. 28.

As ion implantation IM101, oblique ion implantation of p-type impurities is performed. A region PL100, where p-type impurities are implanted by ion implantation IM101 in the semiconductor substrate 1, is shown in FIG. 28. The region PL100 is formed along the bottom and side surface of the trench 104 in the semiconductor substrate 1. The region PL100 includes a region PL101 located in the p-type semiconductor layer EP, a region PL102 located in the n-type buried layer BL, and a region PL103 located in the p-type substrate region SB.

It is desirable for the amount of p-type impurities implanted into the region PL101 by ion implantation IM101 to be large. This is because if the amount of p-type impurities implanted into the region PL101 by ion implantation IM101 is small, the n-type semiconductor region NR may remain in the p-type semiconductor layer EP even after ion implantation IM101. It is necessary for the conductivity type of region PL101 to be p-type, and for this purpose, it is necessary to implant p-type impurities at a higher concentration than the n-type impurity concentration in the n-type semiconductor region NR into the region PL101 by ion implantation IM101.

On the other hand, it is desirable for the amount of p-type impurities implanted into the region PL102 by ion implantation IM101 to be small. This is because if the amount of p-type impurities implanted into the region PL102 by ion implantation IM101 is large, there is a possibility that the conductivity type of the region PL102 may become p-type. If the conductivity type of the region PL102 becomes p-type, the p-type substrate region SB and the p-type semiconductor layer EP may become conductive through the p-type region PL102. It is necessary to prevent the p-type substrate region SB and the p-type semiconductor layer EP from becoming conductive through the p-type region PL102. Therefore, it is necessary to prevent the conductivity type of the region PL102 from becoming p-type, and for this purpose, it is desirable for the amount of p-type impurities implanted into the region PL102 by ion implantation IM101 to be small.

Therefore, it is desirable for the amount of p-type impurities implanted into the region PL101 by ion implantation IM101 to be large, and for the amount of p-type impurities implanted into the region PL102 by ion implantation IM101 to be small. However, even if the conditions of ion implantation IM101 are adjusted, it is difficult to achieve both increase the amount of p-type impurities implanted into the region PL101 and decrease the amount of p-type impurities implanted into region PL102.

### Main Features and Effects

The semiconductor device of the embodiment has the trench 4 that penetrates through the p-type semiconductor layer EP and the n-type buried layer BL and reaches the p-type substrate region SB, and the DTI region 5 formed in the trench 4.

One of the main features is that the plurality of scallops 6 are formed at the side surface of the trench 4, and the plurality of scallops 6 include the plurality of scallops 6d formed at the side surface of the trench 4 in the p-type semiconductor layer EP and the plurality of scallops 6e formed at the side surface of the trench 4 in the n-type buried layer BL. The size L1d of each of the plurality of scallops 6d is larger than the size L1e of each of the plurality of scallops 6e.

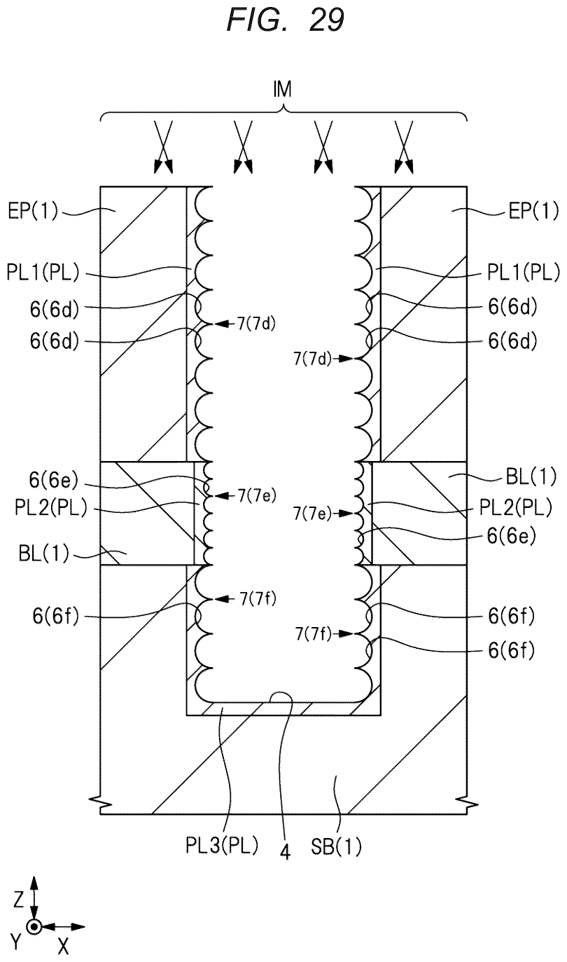

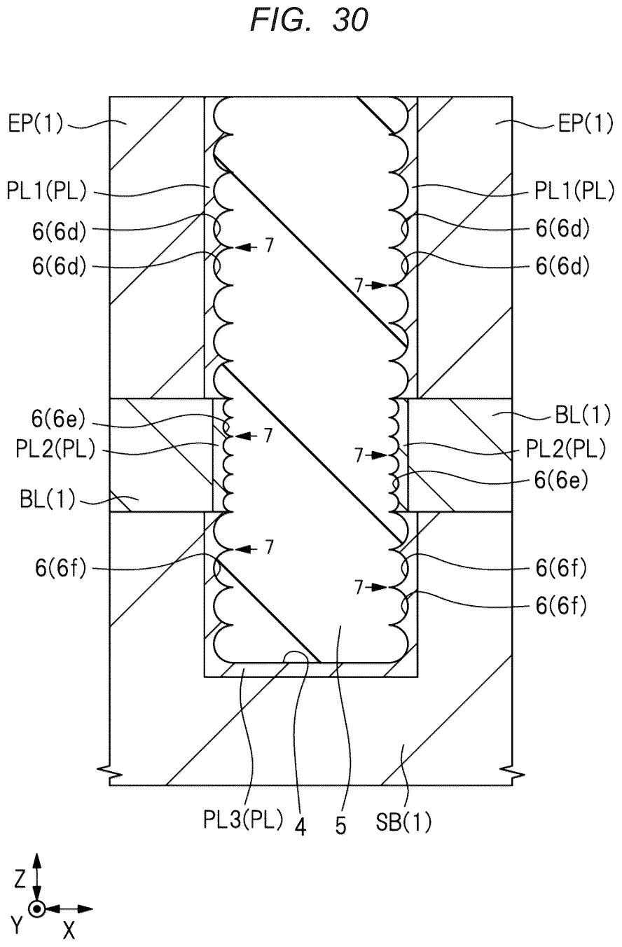

FIG. 29 is a partially enlarged cross-sectional view of a part of FIG. 8. FIG. 30 is a partially enlarged cross-sectional view of a part of FIG. 1, but the region PL into which p-type impurities are implanted by ion implantation IM is also shown in FIG. 30.

The reason for performing the ion implantation IM shown in FIG. 29 is the same as the reason for performing the above ion implantation IM101. That is, when the n-type buried layer BL is etched in the step of forming the trench 4, etching residues containing n-type impurities are generated and adhere to the side surface of the trench 4 in the p-type semiconductor layer EP, thereby creating a possibility that an n-type semiconductor region may be formed in the p-type semiconductor layer EP along the side surface of the trench 4.

After forming the trench 4, as shown in FIGS. 8 and 29, ion implantation IM of p-type impurities is performed, and p-type impurities are implanted into the semiconductor substrate 1 exposed from the trench 4. In ion implantation IM, it is necessary to implant p-type impurities into the side surface of the trench 4. Therefore, it is desirable to apply oblique ion implantation of p-type impurities as ion implantation IM.

The region PL into which p-type impurities are implanted by ion implantation IM is formed along the bottom and side surface of the trench 4 in the semiconductor substrate 1. As shown in FIGS. 29 and 30, the region PL includes a region PL1 located in the p-type semiconductor layer EP, a region PL2 located in the n-type buried layer BL, and a region PL3 located in the p-type substrate region SB.

By increasing the size L1d of each of the plurality of scallops 6d formed on the side surface of the trench 4 in the p-type semiconductor layer EP, the amount of p-type impurities implanted into the region PL1 by ion implantation IM can be increased. The reason is as follows.

By increasing the size L1d of the scallop 6d, the protrusion amount of the protrusion 7d can be increased, and the effective area (surface area) of the side surface of the trench 4 in the p-type semiconductor layer EP can be increased. If the protrusion amount of the protrusion 7d is large, the amount of p-type impurities implanted from the surface of the protrusion 7d into the p-type semiconductor layer EP increases. If the effective area (surface area) of the side surface of the trench 4 in the p-type semiconductor layer EP is large, the amount of p-type impurities implanted from the side surface of the trench 4 into the p-type semiconductor layer EP increases. As a result, the amount of p-type impurities implanted into the region PL1 by ion implantation IM can be increased.

If the size L1d of the scallop 6d is large, the probability that p-type impurities reflected by the scallop 6d are implanted into the p-type semiconductor layer EP increases. As a result, the amount of p-type impurities implanted into the region PL1 by ion implantation IM can be increased.

By reducing the size L1e of each of the plurality of scallops 6e formed at the side surface of the trench 4 in the n-type buried layer BL, the amount of p-type impurities implanted into the region PL2 by ion implantation IM can be reduced. The reason is as follows.

By reducing the size L1e of the scallop 6e, the unevenness (steps) of the side surface of the trench 4 in the n-type buried layer BL is reduced, and the flatness of the side surface of the trench 4 in the n-type buried layer BL is improved. Therefore, by reducing the size L1e of the scallop 6e, the influence of the protrusion 7e is reduced, and the increase in the effective area (surface area) of the side surface of the trench 4 due to the scallop 6e can be suppressed. As a result, the amount of p-type impurities implanted into the region PL2 by ion implantation IM can be reduced.

Increasing the size L1 of the scallop 6 acts to increase the amount of p-type impurities implanted into the region PL by ion implantation IM, and reducing the size L1 of the scallop 6 acts to decrease the amount of p-type impurities implanted into the region PL by ion implantation IM. Therefore, the size L1d of the scallop 6d is made larger than the size L1e of the scallop 6e. This allows the amount of p-type impurities implanted into the region PL1 by ion implantation IM to be greater than the amount of p-type impurities implanted into the region PL2 by ion implantation IM. As a result, it is possible to achieve both an increase in the amount of p-type impurities implanted into the region PL1 by ion implantation IM and decreasing the amount of p-type impurities implanted into the region PL2 by ion implantation IM. This can improve the performance of the semiconductor device.

That is, by increasing the amount of p-type impurities implanted into the region PL1 by ion implantation IM, the conductivity type of the region PL1 can be reliably made p-type, thereby preventing the presence of unnecessary n-type semiconductor regions like the above-mentioned n-type semiconductor region NR in the p-type semiconductor layer EP. As a result, it is possible to prevent the operation of parasitic transistors from being promoted due to unnecessary n-type semiconductor regions like the above-mentioned n-type semiconductor region NR. Furthermore, by reducing the amount of p-type impurities implanted into the region PL2 by ion implantation IM, it becomes easier to maintain the conductivity type of the region PL2 as n-type, thereby accurately preventing the p-type substrate region SB and the p-type semiconductor layer EP from becoming conductive through the region PL2.

Therefore, in the manufactured semiconductor device, the region PL1 is a p-type semiconductor region, and the region PL2 is an n-type semiconductor region. The region PL1 is formed along the side surface of the trench 4 in the p-type semiconductor layer EP and is in contact with the DTI region 5. The region PL2 is formed along the side surface of the trench 4 in the n-type buried layer BL and is in contact with the DTI region 5. The p-type impurity concentration of the region PL1 is preferably higher than the p-type impurity concentration of the p-type semiconductor layer EP.

The size L1 of the scallop 6 can be controlled by factors such as the etching amount in the isotropic etching step of step S4. The etching amount of the p-type semiconductor layer EP in step S4 (etching amount in the Z direction) is made larger than the etching amount of the n-type buried layer BL in step S4 when isotropically etching the n-type buried layer BL. This allows the size L1d of the scallop 6d to be made larger than the size L1e of the scallop 6e. The etching amount in step S4 can be controlled by factors such as the etching time in step S4. By increasing the etching time in step S4, the etching amount in step S4 can be increased.

The plurality of scallops 6 formed at the side surface of the trench 4 further include the plurality of scallops 6f formed at the side surface of the trench 4 in the p-type substrate region SB. It is preferable that the size L1f of each of the plurality of scallops 6f is larger than the size L1e of each of the plurality of scallops 6e. The reason is as follows.

It is undesirable for the n-type semiconductor region NR to be formed in the p-type semiconductor layer EP along the side surface of the trench 4. This is because the n-type semiconductor region formed in the p-type semiconductor layer EP may configure part of a parasitic transistor. In comparison, the adverse effect of forming an n-type semiconductor region in the p-type substrate region SB along the side surface of the trench 4 is smaller.

On the other hand, reducing the size L1 of the scallop 6 increases the time required for the etching step in FIG. 7, while increasing the size L1 of the scallop 6 reduces the time required for the etching step in FIG. 7. This is because the smaller the size L1 of the scallop 6, the more cycles of steps S2, S3, S4, and S5 are required.

Therefore, the size L1f of the scallop 6f is made larger than the size L1e of the scallop 6e. This allows the time required to form the trench 4 in the p-type substrate region SB after penetrating through the n-type buried layer BL to be suppressed. As a result, the time required for the etching step in FIG. 7 can be shortened. Consequently, the manufacturing time of the semiconductor device can be reduced. Additionally, the throughput of the semiconductor device can be improved.

Therefore, it is preferable to increase the size L1d of the scallop 6d, decrease the size L1e of the scallop 6e, and increase the size L1f of the scallop 6f. For this reason, the size L1d of the scallop 6d is made larger than the size L1e of the scallop 6e, and the size L1f of the scallop 6f is made larger than the size L1d of the scallop 6d, which is larger than the size L1e of the scallop 6e. This allows for an increase in the amount of p-type impurity implanted into the region PL1 by ion implantation IM, a decrease in the amount of p-type impurity implanted into the region PL2 by ion implantation IM, and suppression of the time required for the etching step in FIG. 7.

The etching amount of the p-type substrate region SB in step S4 when isotropically etching the p-type substrate region SB is made larger than the etching amount of the n-type buried layer BL in step S4 when isotropically etching the n-type buried layer BL. This allows the size L1f of the scallop 6f to be made larger than the size L1e of the scallop 6e.

When the width of the trench 4 is large, it is easy to implant p-type impurities into the p-type semiconductor layer EP from the side surface of the trench 4 by performing oblique ion implantation after forming the trench 4. However, when the width of the trench 4 is 1 micrometer or less, it is difficult to implant p-type impurities into the p-type semiconductor layer EP from the side surface of the trench 4 by performing oblique ion implantation after forming the trench 4. By forming the plurality of scallops 6 at the side surface of the trench 4 as described above, even when the width of the trench 4 is 1 micrometer or less, the amount of p-type impurities implanted into the p-type semiconductor layer EP from the side surface of the trench 4 can be increased. Therefore, the present embodiment is highly effective when applied to cases where the width of the trench 4 is 1 micrometer or less.

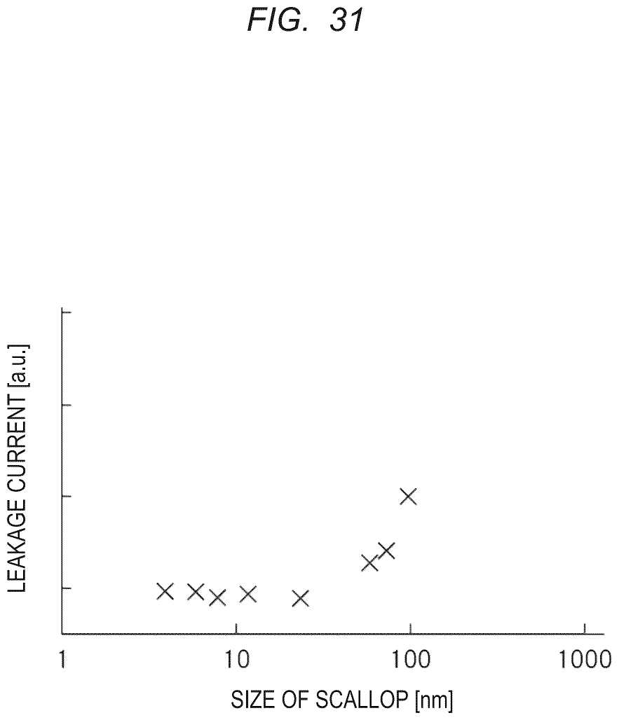

FIG. 31 is a graph showing the correlation between the size L1e of the scallop 6e and the leakage current between the p-type substrate region SB and the p-type semiconductor layer EP. The horizontal axis of the graph in FIG. 31 corresponds to the size L1e of the scallop 6e. The vertical axis of the graph in FIG. 31 corresponds to the leakage current between the p-type substrate region SB and the p-type semiconductor layer EP.

From the graph in FIG. 31, it can be seen that when the size L1e of the scallop 6e is 20 nm or less, the leakage current between the p-type substrate region SB and the p-type semiconductor layer EP can be sufficiently suppressed. Therefore, it is preferable that the size L1e of the scallop 6e is 20 nm or less.

The size L1e of the scallop 6e can be controlled by the etching amount of the n-type buried layer BL when isotropically etching the n-type buried layer BL in step S4. For example, by setting the etching amount of the n-type buried layer BL in step S4 (etching amount in the Z direction) to 60 nm or less, the size L1e of the scallop 6e can be made 20 nm or less.

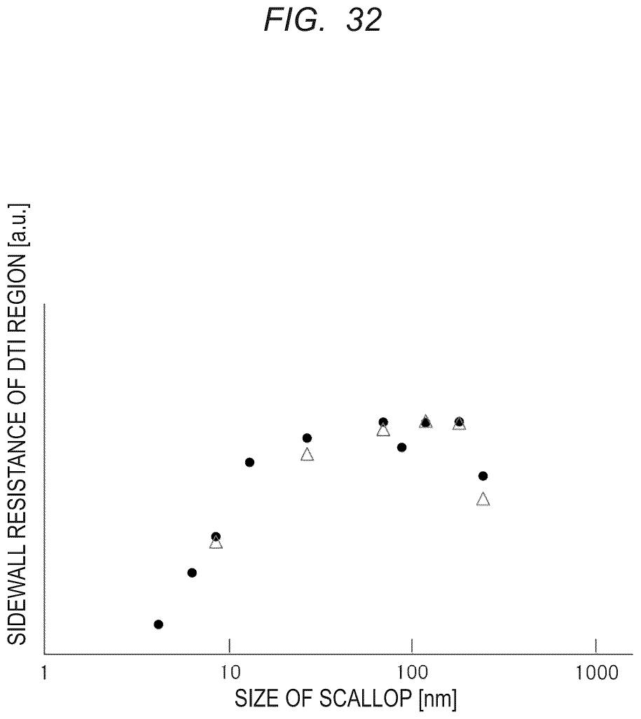

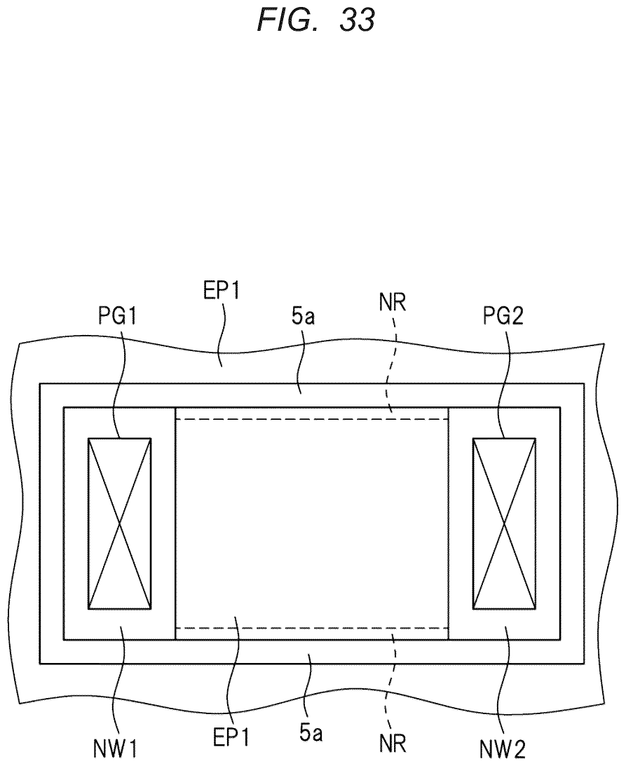

FIG. 32 is a graph showing the correlation between the size of the scallop and the sidewall resistance of the DTI region. The horizontal axis of the graph in FIG. 32 corresponds to the size of the scallop. The vertical axis of the graph in FIG. 32 corresponds to the sidewall resistance of the DTI region. FIG. 33 is a plan view showing a test pattern for measuring the sidewall resistance of the DTI region.

The test pattern shown in FIG. 33 includes the n-type region NW1 and the n-type region NW2 formed in the p-type semiconductor layer EP1 of a test semiconductor substrate, a plug PG1 disposed on the n-type region NW1, a plug PG2 disposed on the n-type region NW2, and a test DTI region 5a in contact with both the n-type region NW1 and the n-type region NW2. The plurality of scallops are formed at the side surface of the trench in which the DTI region 5a is buried. The sidewall resistance of the DTI region 5a is measured by the electrical resistance between the plug PG1 and the plug PG2.

When the n-type semiconductor region NR is formed in the p-type semiconductor layer EP1 along the sidewall of the DTI region 5a, the n-type region NW1 and the n-type region NW2 conduct through the n-type semiconductor region NR, resulting in a lower sidewall resistance of the DTI region 5a. In contrast, when the n-type semiconductor region NR is not formed in the p-type semiconductor layer EP1 along the sidewall of the DTI region 5a, no conductive path is formed along the sidewall of the DTI region 5a, resulting in a higher sidewall resistance of the DTI region 5a.

Therefore, the size of the sidewall resistance of the DTI region 5a can be used to evaluate whether the n-type semiconductor region NR is formed along the sidewall of the DTI region 5a. In other words, if the sidewall resistance of the DTI region 5a is large, it can be determined that the n-type semiconductor region NR is not formed along the sidewall of the DTI region 5a. The absence of the n-type semiconductor region NR along the sidewall of the DTI region 5a means that the n-type impurities in the n-type semiconductor region NR can be offset by the p-type impurities implanted after trench formation (corresponding to the above-mentioned ion implantation IM).

From the graph in FIG. 32, it can be seen that when the size of the scallop is less than 20 nm, the sidewall resistance of the DTI region decreases. From the graph in FIG. 32, it can be seen that when the size of the scallop is greater than 150 nm, the sidewall resistance of the DTI region decreases. When the size of the scallop is 20 nm or more and 150 nm or less, the sidewall resistance of the DTI region is large. When the size of the scallop is greater than 150 nm, the protrusion 7 easily shields the implantation of p-type impurities into the p-type semiconductor layer EP1 from the scallop, which is thought to result in a decrease in the sidewall resistance of the DTI region.

Therefore, it is preferable that the size L1d of the scallop 6d is 20 nm or more and 150 nm or less. By setting the size L1d of the scallop 6d in the range of 20 nm or more and 150 nm or less, the amount of p-type impurities implanted into the region PL1 by ion implantation IM can be increased, thereby preventing the presence of unnecessary n-type semiconductor regions like the n-type semiconductor region NR along the DTI region in the p-type semiconductor layer EP.

The size L1d of the scallop 6d can be controlled by the etching amount of the p-type semiconductor layer EP when isotropically etching the p-type semiconductor layer EP in step S4. For example, by setting the etching amount of the p-type semiconductor layer EP in step S4 (etching amount in the Z direction) to 60 nm or more and 450 nm or less, the size L1d of the scallop 6d can be set to 20 nm or more and 150 nm or less.

The invention made by the present inventor has been described above in detail based on the embodiment, but the present invention is not limited to the embodiment described above, and needless to say that various modifications can be made without departing from the gist thereof.

In the above embodiment, the case where the Zener diode 2 is formed as a semiconductor element in the p-type semiconductor layer EP surrounded by the DTI region 5 and the n-type buried layer BL has been described. When the Zener diode 2 is formed in the p-type semiconductor layer EP, and the n-type semiconductor region NR is formed in the p-type semiconductor layer EP along the side surface of the trench 4, the n-type semiconductor region NR configures part of a parasitic transistor and acts to promote the operation of the parasitic transistor.

In the embodiment, an n-channel LDMOSFET (Laterally Diffused Metal Oxide Semiconductor Field Effect Transistor) may also be formed as a semiconductor element in the p-type semiconductor layer EP, which is surrounded by the DTI region 5 and the n-type buried layer BL. Even when an n-channel LDMOSFET is formed in the p-type semiconductor layer substrate EP surrounded by the DTI region 5 and the n-type buried layer BL, an n-channel NPN parasitic transistor and a PNP parasitic transistor are formed in the semiconductor substrate SB, thereby potentially forming a parasitic thyristor. When an n-channel LDMOSFET is formed in the p-type semiconductor layer EP, and the n-type semiconductor region NR is formed in the p-type semiconductor layer EP along the side surface of the trench 4, the n-type semiconductor region NR configures part of a parasitic transistor and acts to promote the operation of the parasitic transistor. It should be noted that LDMOSFET includes not only MOSFETs using an oxide film as the gate insulating film but also MOSFETs using insulating films other than oxide films as the gate insulating film. Furthermore, an n-channel LDMOSFET is referred to as an n-type LDMOSFET, and a p-channel LDMOSFET is referred to as a p-type LDMOSFET.

Therefore, the described embodiment is highly effective when applied to cases where a Zener diode or an n-channel LDMOSFET (n-type LDMOSFET) is formed as a semiconductor element in the p-type semiconductor layer EP surrounded by the DTI region 5 and the n-type buried layer BL.

What is claimed is:

1. A semiconductor device comprising:
a semiconductor substrate comprising:
a substrate region of a first conductivity type;
a first semiconductor layer of a second conductivity type opposite the first conductivity type formed on the substrate region; and
a second semiconductor layer of the first conductivity type formed on the first semiconductor layer;
a trench penetrating through the second semiconductor layer and the first semiconductor layer and reaching the substrate region; and
an element isolation region formed in the trench,
wherein a plurality of scallops are formed at a side surface of the trench,
wherein the plurality of scallops comprise:
a plurality of first scallops formed at a side surface of the trench in the second semiconductor layer; and
a plurality of second scallops formed at a side surface of the trench in the first semiconductor layer, and
wherein each size of the plurality of first scallops is larger than each size of the plurality of second scallops.

2. The semiconductor device according to claim 1,
wherein a bottom surface of the trench is deeper than a bottom surface of the first semiconductor layer,
wherein the plurality of scallops comprise a plurality of third scallops formed at a side surface of the trench in the substrate region, and
wherein each size of the plurality of third scallops is larger than each size of the plurality of second scallops.

3. The semiconductor device according to claim 1, further comprising:
a semiconductor element formed in the second semiconductor layer,
wherein the semiconductor element is surrounded by the element isolation region in plan view.

4. The semiconductor device according to claim 3,
wherein the semiconductor element is a Zener diode or an LDMOSFET of the second conductivity type.

5. The semiconductor device according to claim 4,
wherein the Zener diode comprises:
a well region of the first conductivity type formed in the second semiconductor layer; and
a cathode region of the second conductivity type formed in the well region.

6. The semiconductor device according to claim 1, further comprising:
a first semiconductor region of the first conductivity type formed in the second semiconductor layer along the side surface of the trench,
wherein an impurity concentration of the first conductivity type in the first semiconductor region is greater than an impurity concentration of the first conductivity type in the first semiconductor layer.

7. The semiconductor device according to claim 1,
wherein each size of the plurality of first scallops is 20 nm or more and 150 nm or less.

8. The semiconductor device according to claim 7,
wherein each size of the plurality of second scallops is 20 nm or less.

9. A method of manufacturing a semiconductor device, the method comprising:
(a) preparing a semiconductor substrate comprising:
a substrate region of a first conductivity type;
a first semiconductor layer of a second conductivity type opposite the first conductivity type formed on the substrate region; and
a second semiconductor layer of the first conductivity type formed on the first semiconductor layer;
(b) forming a trench penetrating through the second semiconductor layer and the first semiconductor layer and reaching the substrate region;
(c) after the (b), performing ion implantation of impurities of the first conductivity type into the semiconductor substrate exposed from the trench; and
(d) after the (c), forming an element isolation region in the trench,
wherein in the (b), the trench is formed such that a plurality of scallops are formed at a side surface of the trench,
wherein the plurality of scallops comprise:
a plurality of first scallops formed at a side surface of the trench in the second semiconductor layer; and
a plurality of second scallops formed at a side surface of the trench in the first semiconductor layer, and
wherein each size of the plurality of first scallops is larger than each size of the plurality of second scallops.

10. The method according to claim 9,
wherein the ion implantation in the (c) is oblique ion implantation.

11. The method according to claim 9,
wherein a bottom surface of the trench is deeper than a bottom surface of the first semiconductor layer,
wherein the plurality of scallops comprise a plurality of third scallops formed at a side surface of the trench in the substrate region, and
wherein each size of the plurality of third scallops is larger than each size of the plurality of second scallops.

12. The method according to claim 9,
wherein the (b) comprises a plurality of cycles, and
wherein each of the plurality of cycles comprises:
(b1) forming a protective film on the semiconductor substrate;
(b2) after the (b1), forming an opening in the protective film by anisotropically etching the protective film;
(b3) after the (b2), isotropically etching the semiconductor substrate exposed from the opening of the protective film; and
(b4) after the (b3), removing the protective film.

13. The method according to claim 12,
wherein an etching amount of the second semiconductor layer when isotropically etching the second semiconductor layer in the (b3) is greater than an etching amount of the first semiconductor layer when isotropically etching the first semiconductor layer in the (b3).

14. The method according to claim 13,
wherein a bottom surface of the trench is deeper than a bottom surface of the first semiconductor layer,.
wherein the plurality of scallops comprise a plurality of third scallops formed at a side surface of the trench in the substrate region, and
wherein each size of the plurality of third scallops is larger than each size of the plurality of second scallops.

15. The method according to claim 9,
wherein the (b) comprises a plurality of cycles,
wherein each of the plurality of cycles comprises:
(b1) forming a protective film on the semiconductor substrate;
(b2) after the (b1), forming an opening in the protective film by anisotropically etching the protective film;
(b3) after the (b2), isotropically etching the semiconductor substrate exposed from the opening of the protective film; and
(b4) after the (b3), removing the protective film,
wherein an etching amount of the second semiconductor layer when isotropically etching the second semiconductor layer in the (b3) is greater than an etching amount of the first semiconductor layer when isotropic etching the first semiconductor layer in the (b3), and
wherein an etching amount of the substrate region when isotropically etching the substrate region in the (b3) is greater than the etching amount of the first semiconductor layer when isotropically etching the first semiconductor layer in the (b3).

16. The method according to claim 9, comprising:
(e) forming a semiconductor element in the second semiconductor layer,
wherein the semiconductor element is surrounded by the element isolation region in plan view.

17. The method according to claim 16,
wherein the semiconductor element is a Zener diode or an LDMOSFET of the second conductivity type.

18. The method according to claim 17,
wherein the Zener diode comprises:
a well region of the first conductivity type formed in the second semiconductor layer; and
a cathode region of the second conductivity type formed in the well region.

19. The method according to claim 9,
wherein each size of the plurality of first scallops is 20 nm or more and 150 nm or less.

20. The method according to claim 19,
wherein each size of the plurality of second scallops is 20 nm or less.
